(19) United States
(12) Patent Application Publication
(10) Pub. No.: US 2025/0389765 A1
(43) Pub. Date: Dec. 25, 2025

(54) SYSTEMS AND METHODS FOR DIRECT-TO-RF SOFTWARE-DEFINED RADIO IMPLEMENTATION OF AN ACTIVE LOAD-PULL SYSTEM

(71) Applicant: Focus Microwaves, Inc., Saint-Laurent (CA)

(72) Inventors: Mohammed Aamir Sheikh, Cardiff (GB); Walid Kamali, Montreal (CA)

(73) Assignee: Focus Microwaves, Inc., Saint-Laurent (CA)

(21) Appl. No.: 19/244,708

(22) Filed: Jun. 20, 2025

Related U.S. Application Data
(60) Provisional application No. 63/662,493, filed on Jun. 21, 2024.

(51) Int. Cl. G01R 31/28; G01R 31/319

(52) U.S. Cl. CPC G01R 31/2822; G01R 31/2837; G01R 31/31905

(57) ABSTRACT

Systems and methods for direct-to-RF (radio frequency) software-defined radio implementation of an active load-pull system are provided. A system may include a controller, a primary field-programmable gate array (FPGA) to control and collect waveform data from vector signal analyzers (VSAs), each comprising an analog-to-digital converter (ADC) connected to an ADC signal-conditioning circuit to directly capture RF measurements of an input signal at an RF fundamental frequency of test and harmonics, each ADC signal-conditioning circuit altering a signal amplitude and isolating a wanted RF frequency of measurement at either the RF fundamental frequency of test or a harmonic to be received by its ADC, first and second couplers generating each input signal by extracting forward and reverse traveling waves at RF from input and output ports of a device under test (DUT), the VSAs capturing the input signals directly at the RF fundamental frequency of test or a harmonic.

### CROSS-REFERENCE TO RELATED APPLICATION(S)

This application claims priority to and the benefit of U.S. Provisional Patent Application No. 63/662,493, filed on Jun. 21, 2024, the entire disclosure of which is incorporated herein for all purposes.

### TECHNICAL FIELD

This disclosure generally relates to semiconductor device testing, particularly to load-pull measurements of a semiconductor device under test (DUT), and more particularly to direct-to-RF (radio frequency) software-defined radio implementation of an active load-pull system.

### BACKGROUND

Some conventional semiconductor test systems do not allow for modulated signal measurements. Some conventional systems may handle load-pull measurements for modulated signals using active closed- or open-loop operations, but require equipment-dictated frequency resolution that is slow and prohibits optimization of measurement speed versus accuracy. An active load-pull system includes multiple synchronized signal sources. Some conventional systems may use channel estimation filters to reduce the effect of noise in reflection coefficient and S-parameter measurements where only a single input signal is applied at the input or output ports of the DUT. Some conventional test systems use a device that is commercially available and when properly deployed reduces overhead and allow for active load pull. However, none of the conventional systems provide direct sampling of the radio frequency (RF) signal.

Until recently, commercially available analog-to-digital converters (ADCs) did not have high enough sample rates to directly sample an RF signal in a semiconductor DUT. As such, the conventional systems required an extra step of down-converting the input signal before the signal can be sampled by the ADCs. This extra step adds time for processing, as well as complexity, and therefore cost, to the conventional systems.

FIG. 1 is a schematic block diagram of a measurement arrangement of a related art system. FIG. 2A is a schematic block diagram of the coupler of FIG. 1. FIG. 2B is a schematic block diagram of the wideband analog-to-digital conversion block of FIG. 1.

FIG. 1 depicts a flow chart outlining a related art of active load-pull diagram for a microwave device. In FIG. 1 a general block diagram is shown of what may be referred to as an open-loop load-pull system. A device under test (DUT) 1 is indicated with two broken lines at each side, which represent the calibrated reference planes for the DUT 1 at the input and output side. The general blocks indicated in FIG. 1 may be explained in further detail below.

Measurement signals are obtained at both sides of the DUT 1 using couplers 4, 5, with a down-converting linear mixer 55 or in-phase and quadrature IQ demodulator (FIG. 2A). For this frequency down-conversion it receives a local oscillator signal from local oscillator block 2. The frequency down-converted measurement signals from both the input side and output side of the DUT 1 are input to a wideband analog-to-digital (ADC) conversion block 3. This analog-to-digital conversion block 3 provides the information required to find the necessary signals to be injected into the source and load side of the DUT 1. For this injection, the waveform information is downloaded in arbitrary waveform signal generators, which are part of injection signal generators 7, 8, as shown in FIG. 1. Also, the intended radio frequency (RF) test signal is downloaded to an arbitrary waveform signal generator, which, in the set-up as shown in FIG. 1, is part of injection signal generator 7 (source). The waveform generation can be of the IQ type (or a digitally generated intermediate frequency (IF)), the resulting signals of these generators are frequency up converted using IQ modulators. The signals needed to control the reflection coefficients at the different frequency are combined using frequency combining networks (e.g., a diplexer or triplexer), which again form part of the injection signal generators 7, 8. The resulting signals are presented to the source and load side of the DUT 1 through the coupler blocks 4, 5 and bias tees 11, 12. Additionally, a baseband signal can be generated using baseband block 9 and injected to the DUT through the bias tees 11, 12 for the source and load side of the DUT 1. Every component in the measurement system is synchronized and operates according to a common reference time base.

In FIG. 2A and FIG. 2B, several blocks of the block diagram of FIG. 1 are shown in more detail. FIG. 2A depicts how load-pull signals are frequency-down-converted prior to being digitized. FIG. 2A shows one of the couplers blocks 4, 5, in this case the coupler block 5 on the load side of DUT 1. The coupler block 5 includes a coupler 51, which can extract a forward and backward traveling wave from the DUT 1. Each is further split using power splitters 52, through a high pass filter 53 and an attenuator 54, and input to a mixer 55 (together with suitable local oscillator (LO) signals from LO block 2). In this manner, signals representing a2,f0; a2,2f0; b2,f0; and b2,2f0 are obtained, which are input to the wideband ADC block 3. The process of separating the fundamental frequency from the higher harmonics in the detection pathway is implemented to preserve the maximum dynamic range for the higher harmonics. This is because removing the fundamental frequencies diminishes the effects of mixer non-linearities during the detection of the higher harmonics.

FIG. 2B depicts an embodiment of the frequency conversion sequentially applied on multiple harmonics after the fundamental and harmonics have been down converted to an intermediate frequency. FIG. 2B shows in more detail the wideband ADC block 3. This block includes the actual analog-to-digital converters (ADCs) 31, one for each of the forward and backward traveling waves at each of the source and load side of the DUT 1, as well as one for the actual source signal. Furthermore, this block includes multiple selectors 33 receiving signals from the ADCs 31 via filters 32. The ADCs 31 operate with a first frequency resolution, dependent on the IF down-conversion and the sample rate of the ADCs 31. The related art system of FIG. 1 and FIG. 2B includes the extra step of down converting the input signal to obtain an IF before the signal can be sampled by the ADCs. Again, this extra step adds time for processing, as well as complexity, and therefore cost, to the related art system.

Accordingly, there is a need for systems and methods for direct-to-RF software-defined radio implementation of an active load-pull system.

### SUMMARY

This disclosure pertains to systems and methods for direct-to-RF software-defined radio implementation of an active load-pull system.

In some aspects, the techniques described herein relate to a system for active load-pull measurements of a semiconductor device under test (DUT), including: a controller, a primary field-programmable gate array (FPGA) operably connected to the controller, the primary FPGA being configured to control and collect waveform data from a first plurality of vector signal analyzers (VSAs), each of the first plurality of VSAs including a respective analog-to-digital converter (ADC) connected to a respective ADC signal-conditioning circuit configured to directly capture radio frequency (RF) measurements of an input signal at an RF fundamental frequency of test and a plurality of harmonics, each ADC signal-conditioning circuit being configured to alter a signal amplitude and to isolate a wanted RF frequency of measurement at either the RF fundamental frequency of test or one of the plurality of harmonics to be received by its corresponding ADC, first and second couplers respectively configured to generate the input signal for each ADC by extracting forward and reverse traveling waves at RF respectively from input and output ports of the DUT, wherein the first plurality of VSAs are configured to capture the input signals directly at the RF fundamental frequency of test or the plurality harmonics over a user-specified frequency bandwidth centered at the RF fundamental frequency of test or one of the plurality harmonics and for a duration of time specified by a user, wherein the FPGA is further configured to control and to send waveform data to a first plurality of vector signal generators (VSGs) respectively including digital-to-analog converters (DACs), each DAC being configured to transmit a respective signal directly at the RF fundamental frequency of test or at one of the plurality of harmonics, each DAC being respectively connected to a DAC signal-conditioning circuit configured to alter a signal amplitude of the signal transmitted from the DAC and filter out unwanted signals, the first plurality of VSGs being configured to transmit respective vector signals directly at the RF fundamental frequency of test or at one of the plurality of harmonics over a user-specified frequency bandwidth centered at the RF fundamental frequency of test or at one of the plurality of harmonics and a duration of time determined by the user, a first amplifier configured to receive a first RF vector signal from a first of the first plurality of VSGs and generate a first amplified RF signal, the first RF vector signal being generated from a forward traveling wave, a second amplifier configured to receive a second RF vector signal from a second of the first plurality of VSGs and generate a second amplified RF signal, the second RF vector signal being generated from a reverse traveling wave, a first circulator configured to: receive the first amplified RF signal from the first amplifier, and transmit the first amplified RF signal to the first coupler, the first coupler being further configured to transmit the first amplified RF signal to the DUT, a second circulator configured to: receive the second amplified RF signal from the second amplifier, and transmit the second amplified RF signal to the second coupler, the second coupler being further configured to transmit the second amplified RF signal to the DUT, a reference generator source configured to provide a waveform connected to a clock control, the clock control being configured to output a plurality of clock signals to the primary FPGA, the ADCs, and the DACs, the clock control signal being configured for synchronizing and triggering measurements for the first plurality of VSAs, the first and second vector signals transmitted to the first plurality of VSGs being synchronized by the clock signal, wherein the controller is further configured to vector error-correct the captured waveform data and the transmitted RF waveforms to a user-specified calibrated reference plane for measurement of DUT parameters at the RF fundamental frequency of test and the plurality of harmonics and of system impedances at the input and output ports of the DUT at the RF fundamental frequency of test and the plurality of harmonics, the waveform measurement data being used to calculate an injection signal at a user-specified DUT port and frequency to alter the impedance at the DUT, the injection signal being synchronized with the input signal to measure a new system state, wherein the measurement at the user-specified calibrated reference plane and frequency is checked against a user-specified impedance setting and user-specified accuracy tolerance, and wherein, in response to the measurement not being within the user-specified accuracy tolerance, a new injection signal is calculated at the corresponding user-specified calibrated reference plane and user-specified frequency bandwidth, and the controller repeats testing until the user-specified accuracy the user-specified accuracy tolerance is reached or when a maximum number of attempts have been made.

In some aspects, the techniques described herein relate to a system, further including: a secondary FPGA operably connected to the controller, the secondary FPGA being connected to a second plurality of VSAs for measurement and impedance control of a second plurality of harmonics, the secondary FPGA being time-synchronized and time-aligned with the primary FPGA via a clock signal frequency and a trigger signal, the secondary FPGA being configured to control and to send waveform data to a second plurality of vector signal generators (VSGs) respectively including digital-to-analog converters (DACs), each DAC being configured to transmit a respective signal directly at the RF fundamental frequency of test or at one of the plurality of harmonics, each DAC being respectively connected to a DAC signal-conditioning circuit configured to alter a signal amplitude of the signal transmitted from the DAC and filter out unwanted signals, the second plurality of VSGs being configured to transmit respective vector signals directly at the RF fundamental frequency of test or at the one of the plurality of harmonics over the user-specified frequency bandwidth centered at the RF fundamental frequency of test or at the one of the plurality of harmonics and for the duration of time determined by the user, wherein the plurality of injected signals at the RF fundamental frequency of test and the plurality of harmonics are combined at both the input and output ports of the DUT prior to being received by RF couplers to generate a vector error-corrected multi-harmonic signal to be received at input and output ports of the DUT.

In some aspects, the techniques described herein relate to a system, further including: one or more direct current (DC) power supplies, and DC measurement circuitry operably connected to the one or more DC power supplies and to the primary FPGA, wherein the DC measurement circuitry is configured to use the first plurality of VSAs with their respective ADCs to capture voltage and current at DC, wherein ADC input waveforms are provided by the ADC signal-conditioning circuits that alter the amplitude of input waveform and remove unwanted frequencies within each input waveform, wherein an input signal to each ADC signal-conditioning circuit is provided by voltage and current sense circuits, and is fed a signal from a sense resistor respectively placed at input or output ports of the DUT, and wherein captured voltage and current waveforms are error-corrected to provide measurements at a common reference plane of RF measurements.

In some aspects, the techniques described herein relate to a system, further including a plurality of DC bias tees respectively configured to supply DC power to input or output ports of a DUT.

In some aspects, the techniques described herein relate to a system, further including: a baseband test system configured to provide active load-pull of a DUT, and baseband measurement circuitry including the first plurality of VSAs with respective ADCs to capture traveling waves collected at baseband frequencies and connected to the FPGA, wherein an ADC input waveform is provided by each ADC signal-conditioning circuit that alter amplitude of the input waveform and remove unwanted frequencies within the input waveform, and wherein the input signal to each signal conditioning circuits is provided by one of low-frequency couplers respectively at input and output ports of the DUT, the low-frequency couplers being configured to extract forward and reverse traveling waves measured at baseband frequencies.

In some aspects, the techniques described herein relate to a system, wherein: baseband active load-pull is applied to input and output ports of DUT, and transmitted baseband signals from the first plurality of VSGs are sent to amplifiers connected to respective low-frequency DC bias tees that combine DC power provided by one or more direct current (DC) power supplies with a respective baseband signal provided by a respective VSG, an amplified signal is then passed through a low-frequency coupler and then combined with an RF signal via the DC bias tees, and signal amplitudes are vector error-corrected to present a desired signal at an RF-calibrated reference plane.

In some aspects, the techniques described herein relate to a system, wherein: the first plurality of VSAs with ADCs are connected to a main FPGA for baseband waveform capture, or a second plurality of VSAs with ADCs are connected to a secondary FPGA for baseband waveform capture.

In some aspects, the techniques described herein relate to a system, wherein: the first plurality of VSGs with DACs are connected to a main FPGA for baseband waveform transmission, or a second plurality of VSGs with DACs are connected to a secondary FPGA for baseband waveform transmission.

In some aspects, the techniques described herein relate to a system, wherein a desired impedance and RF fundamental frequency of test are defined by a user before configuration information is provided.

In some aspects, the techniques described herein relate to a system, wherein a desired impedance is set at an RF fundamental frequency of test and plurality of harmonics and baseband frequencies simultaneously by a user before configuration information is provided.

In some aspects, the techniques described herein relate to a system, wherein: at least one of the ADCs captures waveforms over a user-specified bandwidth centered at a user-specified RF fundamental frequency of test or plurality of harmonics, a digitally-converted RF waveform is filtered to remove unwanted signals, a filtered signal is frequency-converted and then digitally down-converted to a lower sample clock rate, waveforms are then transferred to a controller for further processing, at least one of the DACs transmits waveforms over bandwidth at a user specified RF fundamental frequency of test or harmonics, where the controller transfers the waveform data to the primary FPGA and onwards to the at least one of the DACs at a sample rate based on a user-specified load-pull bandwidth requirement, and the waveform data is digitally up-converted to a sample rate of DAC output, then frequency-converted to the RF fundamental frequency of test or one of the plurality of harmonics before conversion into an analog domain output signal.

In some aspects, the techniques described herein relate to a system, wherein filtering, frequency down-conversion, and digital down-conversion of captured waveform data in a digital domain is performed within the primary FPGA or within one of the ADCs.

In some aspects, the techniques described herein relate to a system wherein filtering, digital up-conversion, and frequency up-conversion of transmitted waveform data in a digital domain is performed within the primary FPGA or within one of the DACs.

In some aspects, the techniques described herein relate to a method for a system for active load-pull measurements of a semiconductor device under test (DUT), the method including: configuring and controlling a first plurality of vector signal analyzers (VSAs) to directly capture and to digitize measurements at input and output ports of the DUT at radio frequency (RF) fundamental frequency of test and at a plurality of harmonics, wherein each VSA respectively includes a high sample rate-based analog-to-digital converter (ADC) that directly captures waveforms at RF fundamental frequency of test and are connected to a respective ADC signal-conditioning circuit that control an amplitude of incoming signal and filter out unwanted frequency components, the VSAs output a digitized signal to a primary field-programmable gate array (FPGA) and send waveform data to a controller, the controller generates and transmits waveform data to the primary FPGA to output digitized data to a first plurality of vector signal generators (VSGs), controlling the first plurality of VSGs to directly inject signals at input and output ports of the DUT at the RF fundamental frequency of test and the plurality of harmonics, wherein the first plurality of VSGs respectively include high sample rate DACs that directly transmit signals at RF frequencies and are respectively connected to DAC signal-conditioning circuits that control an amplitude of an output signal and filter out unwanted frequency components, the first plurality of VSGs transmit injected signal through RF couplers and direct current (DC) bias, both placed at respective input and output ports of the DUT, the RF couplers pass through the transmitted injected signal while extracting forward and reverse traveling waves to feed into the first plurality of VSAs, the controller configures a first of the first plurality of VSGs connected to the input port of the DUT and at RF fundamental frequency of test to inject a signal, the controller assesses an impedance of the system at the RF fundamental frequency of test and the plurality of harmonics at both the input and the output ports of the DUT against a user-specified series of impedance targets at the RF fundamental frequency of tests and the plurality of harmonics at the input and the output ports of the DUT to a user-specified level of accuracy, in response to not meeting one of the user-specified series of impedance targets, the controller calculates a magnitude and a phase of an injected signal required to present to the DUT with the one of the user-specified series of impedance targets, and configures one of the first plurality of VSGs at the input or the output port of the DUT at the RF fundamental frequency of test or one of the plurality of harmonics, and the controller repeats a measurement to assess a newly-updated impedance being presented to the DUT, and in response to the repeated measurement not meeting a user-specified impedance target, calculates a new injected signal, and in response to the repeated measurement meeting the user-specified impedance target proceeds to completion of a measurement process.

In some aspects, the techniques described herein relate to a method, wherein: a digitized capture by one of the first plurality of VSAs at the RF fundamental frequency of test or one of the plurality of harmonics is filtered, frequency-converted, and digitally down-converted to a sample rate based on a user-specified load-pull bandwidth for onward transmission of a digitized waveform from the primary FPGA to the controller, and the controller provides waveform data of one or more injected signals at one or more of the RF fundamental frequency of test or one of the plurality of harmonics at the input and output ports of the DUT at a sample rate based on user specified load-pull bandwidth to the primary FPGA for digital up-conversion to a sample rate of at least one of the DACs, and digital frequency-converted to the one or more of the RF fundamental frequency of test or one of the plurality of harmonics and filtering of unwanted signals to be transmitted out of the at least one of the DACs.

In some aspects, the techniques described herein relate to a method, wherein digital functions of digital down-conversion, digital up-conversion, frequency mixing, and digital filtering are performed in a FPGA or in an associated ADC or DAC.

In some aspects, the techniques described herein relate to a method, wherein: a software stored in a non-transitory computer-readable medium includes instructions that, when executed, cause one or more processors to: utilize a pre-determined system model that is vector error-corrected at the RF fundamental frequency of test and the plurality of harmonics, generate a model of the DUT to describe a behavior of the DUT as a function of an injected input signal, measure forward and reverse traveling waves at input and output ports of the DUT, and calculate a correction injected signal to actively load-pull the DUT at a user-specified input or output port of the DUT and frequency that is based on a user target, a system model, or a DUT model, and an injected signal for active load-pull is vector error-corrected to a calibrated reference plane.

In some aspects, the techniques described herein relate to a method, further including: determining a system model by injecting signals using the VSGs at the RF fundamental frequency of test and the plurality of harmonics at the input and output ports of the DUT connected as a through configuration, the VSGs transmit signals through amplifiers, circulators, couplers, and DC bias tees, and error vector-correcting measurements at the RF fundamental frequency of test and the plurality of harmonics using the determined system model.

In some aspects, the techniques described herein relate to a method, wherein: a predetermined system model that is vector error-corrected at the RF fundamental frequency of test and the plurality of harmonics and a DUT model as a function on an input signal are described over frequency using finite impulse response (FIR) filters, and a resolution bandwidth of the input signal is determined as a function of captured signal bandwidth divided by a filter order.

In some aspects, the techniques described herein relate to a method, wherein: a resolution bandwidth of a received signal is described by a FIR filter used to describe a system model and DUT model, and the resolution bandwidth of the received signal is determined to be less than, similar to, equal to, or greater than a resolution bandwidth of a user-selected input signal.

In some aspects, the techniques described herein relate to a method, wherein a process of active load-pull applies at the RF fundamental frequency of test and the plurality of harmonics at the input and output ports of the DUT in parallel or in a sequential manner.

In some aspects, the techniques described herein relate to a method, wherein the method is process applied at baseband frequencies at the input and output ports of the DUT.

In some aspects, the techniques described herein relate to a method, wherein: a respective passive tuner at each of an input or an output port of a DUT applies an impedance at the RF fundamental frequency of test and the plurality of harmonics, and an impedance of each passive tuner can be set at a fixed setting or can be varied during an iterative process at the RF fundamental frequency of test or at least one of the plurality of harmonics.

This summary is provided to introduce a selection of concepts that are further described below in the detailed description. This summary is not intended to identify key or essential features of the claimed subject matter, nor is it intended to be used as an aid in limiting the scope of the claimed subject matter.

Additional features and advantages of embodiments of the disclosure will be set forth in the description which follows, and in part will be obvious from the description, or may be learned by the practice of such embodiments. The features and advantages of such embodiments may be realized and obtained by means of the instruments and combinations particularly pointed out in the appended claims. These and other features will become more fully apparent from the following description and appended claims or may be learned by the practice of such embodiments as set forth hereinafter.

### BRIEF DESCRIPTION OF DRAWINGS

To describe the manner in which the above-recited and other features of the disclosure can be obtained, a more particular description may be rendered by reference to specific implementations thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example implementations, the implementations may be described and explained with additional specificity and detail through the use of the accompanying drawings.

FIG. 1 is a schematic block diagram of a measurement arrangement of a related art system.

FIG. 2A is a schematic block diagram of the coupler of FIG. 1.

FIG. 2B is a schematic block diagram of the wideband analog-to-digital conversion block of FIG. 1.

FIG. 3 is a schematic block diagram of a system according to an example embodiment of the present disclosure configured for a single RF fundamental frequency of test with DC supplies.

FIG. 4 is a schematic block diagram of a system according to an example embodiment of the present disclosure configured for a single RF fundamental frequency of test with DC measurement and DC supplies.

FIG. 5 is a schematic block diagram of a system according to an example embodiment of the present disclosure configured for a single RF fundamental frequency of test with baseband frequency injection and measurement and DC supplies.

FIG. 6 is a schematic block diagram of a system according to an example embodiment of the present disclosure configured for multiple harmonics of the RF fundamental frequency of test at the input and output ports of the DUT with DC measurement and DC supplies.

FIG. 7 is a schematic block diagram of a system according to an example embodiment of the present disclosure configured for multiple harmonics of the RF fundamental frequency of test at the input and output ports of the DUT with baseband frequency injection and measurement and DC supplies.

FIG. 8 is a schematic block diagram of a DC measurement portion of a system utilizing the RF measurement ADCs with signal-conditioning elements according to an example embodiment of the present disclosure.

FIG. 9 is a schematic block diagram of a DC measurement portion of a system utilizing a separate FPGA and set of ADCs with signal-conditioning elements according to an example embodiment of the present disclosure.

FIG. 10 is a schematic block diagram of a baseband test and measurement portion of a system utilizing the same FPGA as the RF test and measurement portion according to an example embodiment of the present disclosure.

FIG. 11 is a schematic block diagram of a baseband test and measurement portion of a system utilizing a separate FPGA according to an example embodiment of the present disclosure.

FIG. 12 is a flow chart outlining the process of load pull with a check condition comparing the measured impedance with the user set impedance.

FIG. 13 is a flow chart of the initialization process to determine the system model.

FIG. 14A and FIG. 14B are flow charts of the digital processes being applied between the computer controller and the high sampling rate ADCs and DACs.

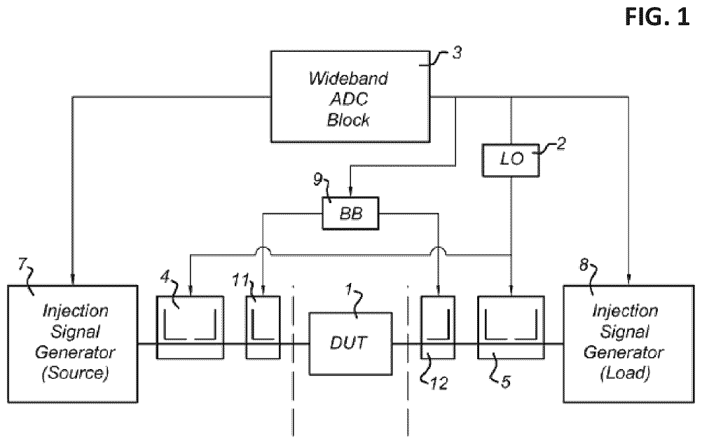

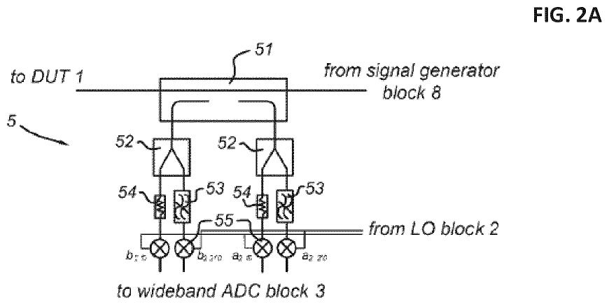

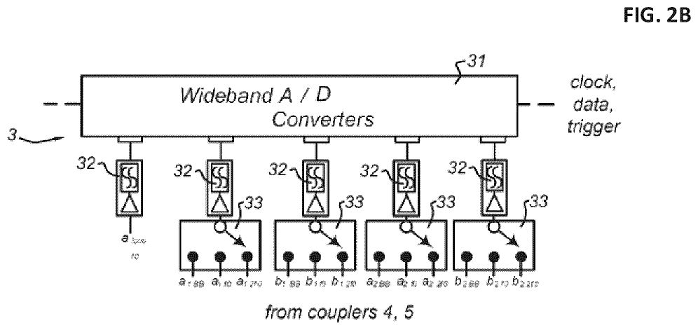

Before explaining the disclosed embodiments of this disclosure in detail, it is to be understood that the invention is not limited in its application to the details of the particular arrangement shown, as the invention is capable of other embodiments. Example embodiments are illustrated in referenced figures of the drawings. It is intended that the embodiments and figures disclosed herein are to be considered illustrative rather than limiting. Also, the terminology used herein is for the purpose of description and not of limitation.

### DETAILED DESCRIPTION

While the subject disclosure applies to embodiments in many different forms, there are shown in the drawings and may be described in detail herein specific embodiments with the understanding that the present disclosure is an example of the principles of the invention. It is not intended to limit the invention to the specific illustrated embodiments. The features of the invention disclosed herein in the description, drawings, and claims can be significant, both individually and in any desired combinations, for the operation of the invention in its various embodiments. Features from one embodiment can be used in other embodiments of the invention.

Embodiments of the present disclosure include semiconductor device testing using load-pull measurements of a semiconductor device under test (DUT). Embodiments may facilitate the full control and measurement of the loading conditions applied at all input and or output ports of a semiconductor DUT at baseband, fundamental, and/or at harmonic frequencies. Embodiments may allow simultaneous measurement of key performance metrics, including: power level, gain, power efficiency, error vector magnitude (EVM) and adjacent channel power ratio (ACPR), baseband currents, baseband voltages, DC current, DC voltages, as well as capturing of time domain phase aligned waveform data for post processing. Embodiments may combine a load-pull method applied on an apparatus to provide a load-pull measurement test system for use in semiconductor device testing.

Systems and methods according to example embodiments of the present disclosure use high-speed digital electronic components, such as analog-to-digital converters (ADCs) and digital-to-analog converters (DACs) within a software-defined radio (SDR) architecture, tailored for load-pull systems. Currently, ADCs and DACs may operate at sample rates above 10 giga-samples per second (GSPS) with a high effective number of bits (ENOB) or resolution, which in turn allows them to be used directly at RF test frequencies and to process these signals without the need to rely on frequency conversion. Up and down frequency conversion methods have been typically used to convert RF signals frequency to an intermediate frequency (IF) both in the RF transmit path (Tx) and the RF receive path (Rx). This new approach according to embodiments significantly simplifies the RF circuitry in both the RF transmit and RF receive signal chains. The very high sample rate of operation also allows transmission and reception of high bandwidth signals at RF test frequencies. Historically, these high-speed components came at the expense of the number of bits that can be transmitted, which limits the signal resolution and consequently the dynamic range. The current state of the art for the DACs is beyond 25 GSPS with greater than 12 bits of control, and for ADCs it is beyond 20 GSPS with greater than 12 bits resolution. In the systems and methods according to embodiments of the present disclosure, there is no down-conversion of the signal and no creation of intermediate frequencies (IFs) because the sample rates of the recently-available ADCs allow for direct sampling at the native frequencies.

“Load-pull” is a field of radio frequency (RF) measurements for characterization of semiconductor devices in a non-50 Ohm (Ω) environment. U.S. Pat. No. 9,625,556 describes a series of mechanically based load-pull tuners that can physically present an impedance to a device under test (DUT). Passive load-pull tuners have been enhanced to independently present impedances over multiple frequencies, and these have been used to characterize DUTs across multiple harmonics, as described in U.S. Pat. No. 7,449,893. These systems are in use, but have limitations in terms of impedance coverage due to losses in the tuners and in additional components, such as cables or couplers between the passive tuners and the DUT. Passive tuners also have limited capability in measuring DUTs using modulated signals with large bandwidths. This is because the impedance naturally varies over frequency, and this impedance skew over bandwidth can become significant as modulated signal bandwidths increase.

Active load-pull systems, such as that described in U.S. Pat. No. 6,639,393, have been developed to electronically synthesize an impedance at the DUT reference plane. These systems can overcome system losses and allow independent impedance control at the frequency of test and harmonics. The system described in U.S. Pat. No. 8,456,175 uses wideband analog-to-digital converters (ADCs) to receive signals, as well as wideband digital-to-analog converters (DACs) to transmit signals. This system requires the use of an intermediate frequency (IF) on both the transmit and receive paths that are frequency converted to the RF fundamental frequency of test for the transmit signal and frequency converted down from the RF fundamental frequency of test for the receive signal. This system allows for load-pull of modulated signals that vary in frequency and time. This system requires the use of IQ Modulators that introduce unwanted components such as local oscillator leakage and frequency-based image components on or close to the frequency of test. These introduce unwanted spurs to the DUT and compromise the quality of the modulated signal in terms of spectral distortion products within and outside of the desired transmit signal and the error vector magnitude (EVM). When frequency down-converting, the mixer can increase the absolute noise power of the system due to the high noise figure of the mixers and the extra noise injected from the LO signal. An alternative active load-pull approach is described in U.S. Pat. No. 7,816,926 that employs a closed-loop control system. This has the same frequency mixing issues as described for U.S. Pat. No. 8,456,175, plus the need for a digital resource intensive delay filter.

Active load-pull systems can characterize semiconductor devices at any frequency from what is typically defined as “AC frequencies” (alternating current), e.g., about 50-60 hertz (Hz), up to and above radio frequencies with wavelengths in the millimeter wave range. Active load-pull systems may provide a means of characterizing active or passive semiconductor device under test (DUT) in a non-50Ω environment. This applies in continuous wave (CW), pulsed RF (PU), direct current (DC) and pulsed RF (DC-PU), as well as modulated signals including multi-tone (MOD) conditions. Active load-pull allows the user to set an impedance at both the input and output ports of the DUT, at the fundamental as well as at harmonic frequencies. The impedance presented can be defined to be of a constant value over the frequency of test, or over a specific bandwidth in frequency or alternatively the impedance presented to the DUT can be varied as a function of frequency to emulate a real-world circuit. The measured outputs are typically defined to be gain, output power, efficiency, linearity, error vector magnitude (EVM) as well as other vector-based derivatives that can be traced back to these parameters. These measurement outputs as a function of impedance are typically displayed over a Smith chart, and can be used to generate contours to aid in the design of passive and active RF components.

Active load-pull systems can be separated into two main categories. The first category of active load-pull systems is an open-loop implementation that has independent transmitter signals at the input and output ports of the DUT. To allow for impedance control, the signal sources have phase and amplitude control. For frequency coherence, a reference signal may be shared across the various signal sources. Impedance convergence to a target in open-loop implementations of active load-pull is typically done in an iterative manner. This is because there is no prior knowledge of the DUT's behavior as a function of impedance, so the system may adjust the load or source-pull source based on a calculation of the vector-based error between the active measurement of the impedance being set by the system and the user-set target. The second category of active load-pull systems are closed-loop systems. Closed-loop load-pull generally involves feeding the output signal of the DUT back at the DUT. Extra phase and amplitude control-based components may be added into the feedback path to enable control of the signal, which in turn controls the impedance presented to the DUT.

Active load-pull systems have been realized by multiple different approaches. One way is through the integration of multiple pieces of measurement equipment, such as vector signal analyzers and vector network generators. This approach may provide an easier development, but may be limited in terms of speed and bandwidth of operation. One alternative approach is to base a solution around ADCs for receiving signals and DACs for transmitting signals. Until recently, these components did not have high enough sample rates to directly sample an RF signal. This then necessitated the use of up- and down-frequency conversion from a design-specified intermediate frequency (IF) to the desired test frequency. These systems can support wide instantaneous bandwidths, but are limited by the IF frequency. A recent development has been the commercial availability of very high-speed ADCs and DACs that are directly useable up to millimeter (mm) wave frequencies. This may negate the need for any frequency conversion, and may simplify the overall hardware architecture of an active load-pull system.

An active load-pull measurement system according to an example embodiment may be used for characterizing a semiconductor device under test (DUT) in a non-50Ω impedance environment to output parameters, such as gain, output power, efficiency, linearity, error vector magnitude (EVM) as well as other vector-based derivatives that can be traced back to these parameters.

An example active load-pull measurement system may include a computer controller with a software-based user interface that may configure, control, and exchange data with one or more field programmable gate arrays (FPGAs). There may be a minimum of one FPGA, e.g., a “primary” FPGA that may be configured to control and receive digitized data from a plurality of analog-to-digital converters (ADCs), and to control and transmit digitized data to a plurality of digital-to-analog converters (DACs). Additional FPGAs may be used, for example, to connect to additional ADCs and DACs. In this case, there may be a plurality of shared clock and trigger signals between the primary FPGA and the additional FPGAs. The ADCs may each be connected to a signal-conditioning element. These may be combined to form a vector signal analyzer (VSA). The signal-conditioning elements may control the signal into the corresponding ADC, e.g., in terms of power and filtering of unwanted signals. The DACs may each be connected to a signal-conditioning element. The signal-conditioning elements connected to the DACs may alter the waveform from the DACs in terms of power, phase, and/or filtering of unwanted signals. These components may form the complete vector signal generator (VSG). Each of the signal-conditioning elements may comprise one or more electronic circuitry components, for example, an electronic filter, e.g., a bandpass filter, a bandpass filter with variable center frequency, a bandpass filter with variable selectivity control, or another type of electronic filter, such as a low-pass filter, a high-pass filter, a band reject filter, etc. The waveform transmitted by the VSG may then be forwarded onto the DUT, e.g., via couplers and DC bias tees. The couplers may allow for the transmitted signal to pass through while extracting the forward and reverse traveling waves. These forward and reverse traveling waves may then be fed into the receivers of the VSAs. The transmitted signals through the couplers may then be fed into the DC bias tees, that may allow for the addition of a DC power source provided to the DUT. There may be multiple VSGs connected to the input and output ports of the DUT. The clock control block may generate a clock signal that may be fed into one or more FPGAs, as well as to the plurality of ADCs and DACs. The clock signal may or may not be at the same frequency for the FPGAs, ADCs and DACs. The clock-control block may take in a fixed signal in frequency and amplitude from the reference source.

The process of load-pull measurement may be initiated by the user's providing a desired target impedance or reflection coefficient at the frequency of test. This may then initiate the computer controller to send configuration information to the plurality of FPGAs, VSAs, and VSGs. This may include information about the frequency of tests, the VSA power setting and the RF power setting of the VSG connected to the input of the DUT for testing. Before transmission of any signal, the signal-conditioning elements connected to the ADCs within the VSA may be configured for the frequency of test by adjustment of filters and adjustment of signal power to the ADC. The ADC may be configured to sample the signal directly at the RF fundamental frequency of test. The DUT may be DC-biased at a user-set voltage and current setting with the connected DC supply, and this may be fed via the DC bias tees at the input and output ports of the DUT. The computer controller may then load an input waveform into the primary FPGA, which could be a continuous-wave (CW) waveform, a pulse waveform, or an arbitrary waveform signal that may vary in amplitude, phase, and/or frequency over time. Each type of waveform may have a defined duration and sample rate. The input VSG may generate the waveform directly at the RF fundamental frequency of test with the signal-conditioning elements configured to adjust the amplitude of the signal and to filter unwanted frequencies originating from the DAC. The input signal may be input into the DUT with the measurement then initiated by the computer controller. The RF measurements process may collect waveforms from the extracted forward and reverse traveling waves by the directional couplers at the input and output ports of the DUT. These forward and reverse traveling waves may then feed into the preconfigured ADCs and signal-conditioning elements directly at the RF fundamental frequency of test. The ADC captures may be triggered by the primary FPGA to collect and digitize the traveling waves and feed the data into the FPGA for onward transmission to the computer controller. The measurements at the computer controller may be corrected in amplitude and phase using a predetermined vector error model of the system. The computer controller may then calculate the required load-pull signal to inject at the output port of the DUT. The configuration of the second VSG at the output of the DUT may then be applied, and a waveform may be sent to be generated directly at the RF fundamental frequency of test to the primary FPGA for onward transmission to the VSG. The waveform playback by the output VSG may be synchronous in frequency, time, and phase with the signal provided by the VSG connected at the input port of the DUT. This process of measurement and output signal adjustment being conducted by the VSG connected to the output port of the DUT may be done until the measurement system has confirmed that the desired impedance set by the user has been successfully achieved.

An example active load-pull system can be expanded to other frequencies of tests. These frequencies can be focused at the higher harmonics of the frequency of test or at low frequencies (e.g., “baseband frequencies”) from DC up to the sampling rate of the input waveform. The user may set the desired impedance at the other frequencies of interest and/or at the input or output port of the DUT. The process may follow what was described earlier with an input signal being input into the input port of the DUT at the RF fundamental frequency of test, but with additional VSGs that correspond to each frequency of test and/or port of the DUT. The process of measurement may be expanded to initiate a loop, whereby the computer controller may cycle through multiple configurations of the FPGA, ADCs, and connected signal elements that correspond to each frequency of measurement for load-pull. At each frequency of measurement, the receiver may collect and digitize RF measurements that may be forwarded onto the FPGA for onward transmission to the computer controller. In some cases, the DC or low-frequency measurements can be done in parallel with an additional set of receivers and an FPGA. The computer controller may then apply a predetermined vector corrected error model of the system. The process of measurement may be conducted until all of the frequencies of tests have been captured and the data transferred to the computer controller. The computer controller may then calculate the required injection signal at each frequency of test and/or port of the DUT. The computer controller may send configuration information to the primary or additional FPGAs, DACs, and connected signal-conditioning elements. The computer controller may then send waveforms to the plurality of FPGAs for onward transmission to the connected VSGs. All of the VSGs may then begin playback synchronously in frequency, time, and phase with the signal provided by the input VSG. The process of measurement and load-pull signal adjustment may continue until all of the user desired impedances at the various frequencies of test and/or ports of the DUT have been achieved.

An example active load-pull system may include mechanical tuners that can be connected at the input or output ports of the DUT. The tuners can be placed directly at the DUT ports, behind the directional couplers, or at any location in between. The computer controller may configure the mechanical tuners to set the impedance at the input frequency of test and, if available, at a higher harmonic frequency. The computer controller may select whether to inject additional signals at the RF fundamental frequency of test dependent and higher harmonics based on the user's desired target impedance to conduct hybrid active load-pull.

An example active load-pull system may include a method for active load-pull measurements of a semiconductor device under test (DUT). The method may include configuring and controlling a plurality of VSAs and VSGs. The method may utilize the VSAs capability to directly capture and digitize waveforms at the RF fundamental frequency of test plus a plurality of harmonics. The method may include collecting the data into the FPGA and applying filtering, frequency mixing, and digital down-conversion techniques to the digitalized data before sending the modified capture to the computer controller. The computer controller may send waveform data to the FPGA for onward transmission to the VSGs. The VSG connected to the input of the DUT may be set to provide an RF signal at the frequency of test to the input port of the DUT. The FPGA may apply filtering, frequency mixing, and digital up-conversion techniques to feed the waveform into the VSG at a high sampling rate to then directly output at the RF fundamental frequency of test plus plurality of harmonics. The process of active load-pull may be initiated by the user inputting a target impedance at the RF fundamental frequency of test for a user-specified level of input excitation. The computer controller may enable the VSG connected at the input port of the DUT, and may obtain measurements at the input and output ports of the DUT. The measurements may form the basis of constructing a model of the DUT. The computer controller may also assess the current system impedance environment at the RF fundamental frequency of test and determine. The computer controller may then use the DUT and a predetermined system to calculate an injected waveform to present the user specified impedance setting. The waveform data may then be sent to the FPGA to then forward the waveform data onto the VSG that may be connected to the output port of the DUT and configured for operation at the RF fundamental frequency of test. The computer controller may then configure the FPGA and VSGs to synchronously transmit the input signal with the newly loaded waveform sent to the VSG connected to the output port of the DUT at RF fundamental frequency of test. The computer control may then re-assess the system impedance presented to the DUT, and may assess the current state of the system against the user-specified target. In the event that the system does not meet the user-specified target within a user-specified level of accuracy, the process may repeat with a newly calculated waveform being sent to the VSG that may be injected at the output port of the DUT. The process may stop once the active load-pull system has successfully achieved the user-specified target or reached a maximum number of iterations, e.g., as specified by the user.

Some example embodiments can be expanded to be applied to a plurality of VSGs connected to the input and output ports of the DUT and configured to operate at the plurality of harmonic frequencies. The user may input the impedance targets at the RF fundamental frequency of test, plus a plurality of harmonics at the input and output ports of the DUT. The computer controller may start the process by injecting a waveform to the input port of the DUT and obtain measurements from the FPGA connected to the VSAs directly at the RF frequency plus the plurality of harmonics. The computer controller may then calculate the injected waveforms at the RF fundamental frequency of test plus the plurality of harmonics based on a model of the DUT plus a predetermined system model for all of the user-specified frequency (ies) and ports. The waveform data for the RF fundamental frequency of test may be sent by the computer controller to the FPGA for onward transmission to the corresponding VSG. The computer controller may also send waveform data to the same or a secondary FPGA for onward transmission to the VSGs configured to operate the plurality of harmonics and ports of the DUT. The computer controller may then measure and assess the impedances presented to the DUT against the user specified targets at the input and output ports of the DUT and at the RF fundamental frequency of test plus plurality of harmonics. If any of the plurality of impedance measurements are outside of the user specified level of accuracy the computer controller may provide new waveform data to the VSG that corresponds to the impedance that failed the accuracy check. This process may repeat until the active load-pull system has successfully achieved the user-specified targets at the RF fundamental frequency of test, plus the plurality of harmonics or the system has reached its maximum number of iterations.

In some example embodiments, the various impedance control loops at the RF fundamental frequency of test plus plurality of harmonics at the input and output ports of the DUT are simultaneously measured and updated. In some example embodiments, the desired impedance may be defined by a user before the configuration information is provided. In some example embodiments, prior to the first measurement being taken, the DUT may be biased with direct-current (DC) supplies via DC bias tees. Some example embodiments may further include combining injection signals for controlling reflection coefficients for fundamental and harmonic frequencies with the frequency de-multiplexing filters. Some example embodiments may further include providing a mechanical tuner connected to at least one of the input port or the output port of the DUT, and operating the mechanical tuner at one or more of a fundamental frequency or at least one harmonic frequency to be tested.

In active load-pull systems, at least two transmit signals are synthesized and simultaneously excite both input and output ports of a device under test (DUT). These signals must be periodic and coherent in phase with controlled magnitudes. Typically, transmitters can also be called vector signal generators (VSG) that allow for magnitude and phase control of the periodic signals. The high-speed DACs mentioned earlier are a particular implementation of a VSG.

The introduction of field-programmable gate arrays (FPGAs) allows for control and synchronization of at least two DACs on the transmit path with a common high-speed clock for improved frequency and phase coherence. The FPGA provides for digitization of the input signals so that the system may be controlled by computers. The first DAC is for the input injection signal, and the second DAC is for the output injection signals. A common trigger can be shared to align the waveforms in time for harmonics also for pulsed and wide bandwidth muti-tone/modulated measurements. Signal-conditioning elements, such as filters for the isolation of specific harmonic frequencies and power control, may still be utilized to increase the dynamic range in terms of power control. Additional amplification may be employed for higher output power capability. Microwave passive tuners may also be used to provide a better match, reducing the need for high power amplifiers. Additional DACs with signal conditioning, as well as clock and trigger signal routing, can be added to allow for control of higher harmonic frequencies or for baseband frequencies.

On the receive side, multiple ADCs can also be synchronized by an FPGA with a common high-speed clock for improved frequency and phase coherence. This allows for parallel capture of the forward (a1, b2) and reverse (b1, a2) traveling waves. A common trigger can be shared to align the capture with the transmit signal from the DACs that are sharing a common trigger. Additional signal-conditioning elements, such as filters for improved sensitivity and attenuators for shifting the capture window in amplitude, may also be utilized. At very low power levels, a low noise amplifier can be added to improve measurement dynamic range in terms of power.

Both the ADCs and DACs have high speed interfaces that use one or more FPGAS, depending on the provided digital resources, such as memory, logic gates, digital signal processing slices (DSPs), and high-speed digital interfaces (e.g., a serializer/deserializer (“SerDes” or “SERDES”)). The FPGA may have to support multiple high-speed interfaces in parallel, for example, to transfer data from a personal computer (PC) to the DACs on the transmit side, and to take measured data from the ADC to the PC on the receive side.

In both cases, extra functionality may be needed within the FPGA to successfully go from one interface to the other. On the transmit side, this may include digital up-converters (DUCs) that increase the sample rate from the original waveform loaded in by the user on the PC to the sample rate of the DAC. Some digital mixing may also be done with internally derived numerically controlled oscillators (NCOs) to output the signal at the desired test frequency. Finally, some finite impulse response (FIR) filters may also be used to filter out any digitally generated unwanted frequency products prior to sending the information to the DACs. On the receive side, the mirror opposite may be employed in that the captured data from the high-speed ADC may be first digitally filtered to remove unwanted components and then mixed down using NCOs, and finally digitally down-converted (DDC) to a sample rate according to the PC's requirements. The FPGA that is directly connected to the DACs may act as the timing reference for all of the ADCs and DACs within the load pull system.

An active load-pull system according to an example embodiment of the present disclosure may provide semiconductor device testing using load-pull measurements of a semiconductor device under test (DUT). An example active load-pull system may allow for full control and measurements of loading conditions at the input and output ports of the semiconductor DUT at DC, baseband, fundamental, and/or harmonic frequencies. An example active load-pull system may allow for the measurement of key performance metrics such as input power, output power, gain, efficiency, spectral emissions, adjacent channel power ratio (ACPR), error vector magnitude (EVM), baseband currents, baseband voltages, baseband spectral emissions, DC currents, and/or DC voltages, as well as capturing of time domain phase-aligned RF waveform data. An example active load-pull system may include a method based on a series of modules and subsystems to provide a load-pull measurement system for semiconductor device testing.

An example active load-pull system may utilize high-speed digital electronic components, such as analog-to-digital converters (ADCs) and digital-to-analog converters (DACs). These may be implemented within a software-defined radio (SDR) architecture, and may be customized for load-pull applications. In a conventional SDR system, the ADCs and DACs are configured to function at an intermediate frequency (IF), and the frequency may then be up- or down-converted to an RF frequency of operation. This was the typical approach due to the desire to have a high dynamic range as defined by the effective number of bits (ENOB) and the state-of-the-art parts available would allow for operation up to 1-2 giga samples per second (GSPS). Example embodiments of the present disclosure may use ultra high-speed ADCs and DACs that function at sample rates of at least ten (10) GSPS, which allow for direct transmission and capture of the RF signals, thus negating the need for any frequency up- or down-conversion. This may simplify the system considerably with a significant reduction in the number of components. The very high sample rates of the DACs and ADCs may also allow for the concurrent transmission and capture of very wide bandwidth signals, e.g., up to 2 GHz. Historically, such high speed ADCs and DACs had limitations in the number of bits, which limited the resolution control and dynamic range. This ruled out the use of such components for active load-pull. The latest state-of-the-art very high-speed DACs can function at greater than 25 GSPS with 12 bits of control, and very high-speed ADCs can function at greater than 20 GSPS with 12 bits of resolution. An example active load-pull system and/or method according to example embodiments of the present disclosure may not include RF frequency up- or down-conversion and may omit an IF because the ADCs and DACs may function directly at the RF fundamental frequency of test.

The very high-speed DACs and ADCs may still require the use of additional RF components. The DAC may be connected to signal-conditioning elements. These may allow for extension of the output power range and for filtering of any unwanted out-of-band signals and/or products that could be sent to the DUT. This complete lineup can be described as a vector signal generator (VSG). The ADC may also be connected to signal-conditioning elements. These may allow for extending the power range of the receiver and for filtering of any unwanted out-of-band signals to improve the receiver's sensitivity. This complete lineup can be described as a vector signal analyzer (VSA).

Multiple VSGs may be required within an example active load-pull system. There may be a minimum of two VSGs. The first VSG may serve as the input signal to the DUT, and may be configured to output at the fundamental frequency of test. The second VSG may serve as the load-pull signal at the output port of the DUT, again at the fundamental frequency of test. Additional VSGs can be added for the higher harmonic frequencies at both the input and output ports of the DUT, as well as for the baseband frequencies at both the input and output ports of the DUT. The signal-conditioning elements within the VSG may include RF attenuators, RF amplifiers, and/or RF filters. The RF attenuators and RF amplifiers may be interchangeable, e.g., through a network of RF switches, and may extend the original power range of the DACs. RF filters may remove any unwanted signal components originating from the DAC and the sequential components to provide a broadband spectrally-clean signal to the DUT.

Multiple VSAs may be included within an example active load-pull system. There may be a minimum of two VSAs within a system. In some examples, four VSAs may be provided within a system. This may be to simultaneously capture the four individual RF traveling waves extracted using couplers, with a1 and b1 captured at the input ports of the DUT, and a2 and b2 captured at the output ports of the DUT. The VSAs can be configured to receive RF waveforms directly at the input frequency of test, at the higher harmonic frequencies, at baseband frequencies, and at DC. This can be done with the use of additional switches to individually capture each separate frequency component. Alternatively, additional VSAs can be added to receive the measurements in parallel. The VSAs may include the ADCs and additional signal-conditioning elements. The signal-conditioning elements may include RF attenuators, RF amplifiers, and/or RF filters. The RF attenuators and RF amplifiers may be interchangeable, e.g., through a network of RF switches, and may extend the original power range of the ADCs. RF filters may remove any unwanted signal components to provide a broadband spectrally-clean signal to the ADC.

The use of field programmable gate arrays (FPGAs) may be required for multiple purposes within an example active load-pull system. One use of an FPGA may be as a data transfer conduit between the computer controller and the front-end digital components, e.g., the ADCs and DACs. Due to the very high sample rates of operation the interface between the individual ADCs and DACs to the FPGA have to operate at a very high clock rate. The same requirement for a high data rate applies between the computer controller and the FPGA, e.g., to ensure swift data transfer. As such, each of these interfaces may use high-speed serializer/deserializer (SERDES)-based protocols. The FPGA should support all these interfaces in parallel, and may manage the data flow in either direction. For example, the FPGA should take waveform data from the computer controller using a high-speed peripheral component interconnect (PCI) standard interface or a similar high-speed alternative, and then may convert the data via serial interface, e.g., a JEDEC® serial interface for data converters (e.g., JESD204™) for the DACs as part of the VSG. On the receive aspect, a serial interface (e.g., JESD204™) may allow for obtaining the data from the ADC, and this may then be converted within the FPGA to a peripheral component interconnect (PCI) interface to send the data to the computer controller.

FPGAs may also act as a timing reference between the plurality of ADCs, DACs, and/or additional FPGAs that may be used within an example active load-pull system. The FPGA may be capable of triggering each digital component to within one clock sample accuracy. In the event of any delays, e.g., due to longer printed circuit board (PCB) trace lengths, the FPGA may be able to compensate for this at a sample level of resolution. This may allow for the repeatable and fully synchronized capture of waveforms via the ADCs and fully synchronized, as well as phase-coherent, transmitters. This may reduce the need for post-processing, such as the use of resource-intensive correlation functions.

When setting up the VSGs, the FPGAs may take waveform data provided by the computer controller in the form of an array of values of a certain number of samples and a defined sample rate. The waveform array of data, initially operating at baseband, may then go through a process of digital up-conversion (DUC) to the DACs' baseband sample rate. The FPGA may then temporarily store the up-sampled waveform array, e.g., into random access memory (RAM), for continuous playback. For this input signal, the FPGA may also assign a trigger point that may be aligned to a fixed sample number within the array. At this point, the primary FPGA may output a trigger both internally and externally for synchronization across the plurality of FPGAs, DACs, ADCs, and/or externally to other pieces of equipment. The up-sampled waveform array can then be adjusted, e.g., in terms of amplitude, phase, and delay of the signal over time and frequency. Then the waveform array may be digitally mixed with an internally derived high-frequency local oscillator (LO) to the frequency of test. The high-frequency array may then be passed through a filter to remove any unwanted digitally-derived frequency products, and for any further frequency-based equalization of the array. Finally, the waveform may be converted for transmission into the serial interface, e.g., a JESD204™-based interface, for onward transmission to the DAC. Due to resource limitations within the FPGA, some of the digital mixing, filtering, and DUC processes may also be present in the DAC, but in a more limited form. This can be done, for example, by configuring the internal settings of the DAC to apply the appropriate settings.

When setting up the VSAs, the FPGAs may take a triggered waveform capture at the RF fundamental frequency of test for a specified duration of time (or number of samples) from the ADC, e.g., via the serial interface. The FPGA may convert the data capture into a single waveform array, and may apply a digital filter to filter out any other unwanted signals. The waveform capture may then be digitally mixed from the RF fundamental frequency of test to the baseband frequency. The baseband waveform capture can then be adjusted in terms of amplitude, phase, and/or delay of the signal over time and frequency. The baseband frequency array may then be digitally down-converted (DDC) to a lower sample rate, and the waveform may then be temporarily stored, e.g., in RAM. The waveform capture may then be converted for onward transmission to the computer controller for further post processing and analysis. Due to resource limitations within the FPGA, some of the digital mixing, filtering, and DDC processes may also be present in the ADC, but in a more limited form. This can be done, for example, by configuring the internal settings of the ADC to apply the appropriate settings.

For frequency and timing purposes, a common reference clock may be used. This reference clock can be sourced internally or provided externally from outside of the system. The reference clock may be fed into a clock generator. The clock generator may adjust the reference clock input in terms of frequency, and may distribute this to the FPGAs, ADCs, and DACs. In some cases, the clock generator may be configured to provide different clock output frequencies to different pieces of digital hardware. The clock and reference outputs may also be exported externally to synchronize to other pieces of equipment.

An example active load-pull system may also include RF couplers to extract the forward and reverse traveling waves at the input and output ports of the DUT. DC bias tees may combine DC and baseband signals with the RF frequency test signal output by the VSG. Isolators or circulators may direct the energy from the DUT to a 50Ω termination, and may simultaneously allow for RF power to be injected to the DUT at the input and output ports of the DUT. Finally, amplifiers may also be used to increase the power of the signal going into the input and output ports of the DUT.

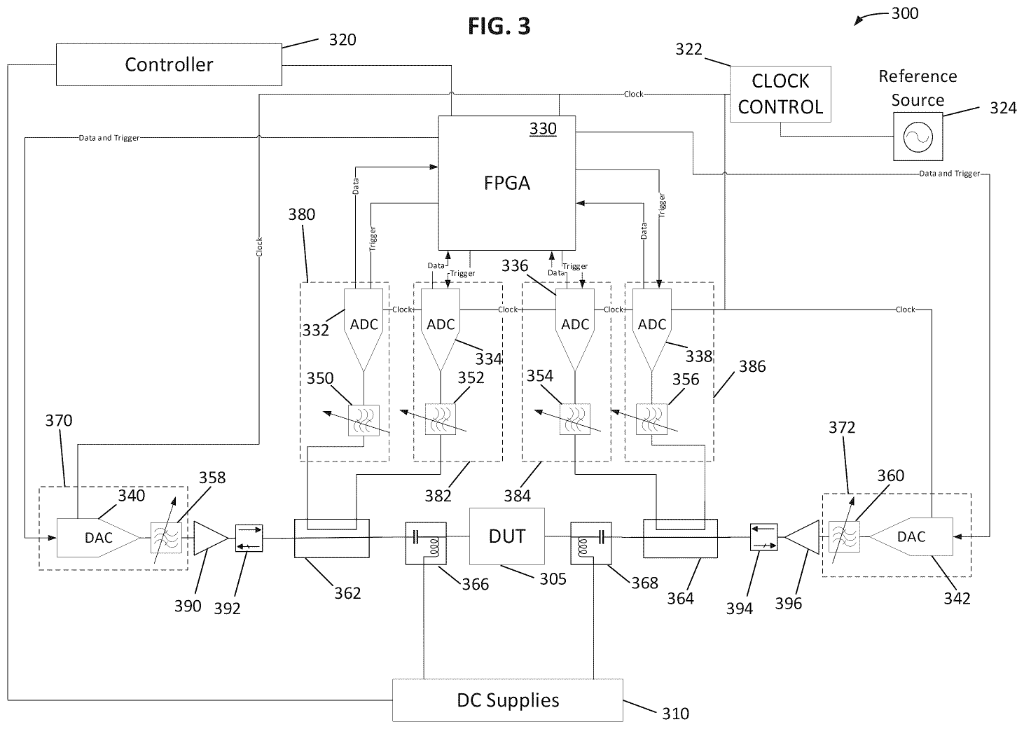

FIG. 3 is a schematic block diagram of a system according to an example embodiment of the present disclosure configured for a single RF fundamental frequency of test with DC supplies.

FIG. 3 depicts an arrangement of an example system 300 according to an example embodiment as applied to a single frequency. When considering the system as shown in FIG. 3, it should be appreciated that there are various alternative arrangements of the apparatus that can be made according to example embodiments of the present disclosure. The illustrated embodiment in FIG. 3 shows the implementation of a fundamental frequency-only active load-pull system with DC signal supplies 310.

A user may first initialize the hardware using software operating within a controller 320. For example, the user may first set a desired target impedance value using software operating within the controller 320, e.g., a computer controller. Alternatively, the target impedance value may be provided by another source. The controller 320 may start sending configuration information to a clock control 322, an FPGA 330, ADCs 332, 334, 336, and 338, and DACs 340 and 342. The clock control 322 may derive the output frequency based on a fixed frequency output from a reference source 324. The frequency of test and the RF input power setting may be set, e.g., by the user, which may prompt the controller 320 to start sending further configuration information to the ADCs 332, 334, 336, and 338 and to connected respective signal-conditioning elements 350, 352, 354, and 356, as well as to the DACs 340 and 342 and connected respective signal-conditioning elements 358 and 360. A DC bias may also be applied, e.g., by a user, to a device under test (DUT) 305 using the DC supplies 310. The DC signal may be delivered to the DUT 305 through DC bias tees 366 and 368. The user may then initiate the measurement.

At this point, the controller 320 may send waveform data to the FPGA 330, which may then digitally up-convert the sample rate of the waveform, may digitally mix the input waveform data to the frequency of test, and then may apply a filter to remove any unwanted frequency-based components. The waveform data, now at the frequency of test, may be sent onwards to a VSG 370 at the input side of the DUT 305. Additional elements may be connected to the VSGs 370 and 372, such as RF amplifiers 390 and 396 and circulators 392 and 394. The RF measurements may be extracted using couplers 362 and 364 that may be connected at the input and output ports of the DUT 305. The RF measurements may then be forwarded onto VSAs 380, 382, 384, and 386, which may directly sample the RF measurements and then provide a digitized output to the FPGA 330. The FPGA may then filter the signal received from the ADCs 332, 334, 336, and 338. The FPGA 330 may then apply filters to remove unwanted frequency components, digitally frequency down-convert from the RF fundamental frequency of test to a baseband signal, and then digitally down-convert the sample rate. The measurements may then be sent onwards to the controller 320.

The controller 320 may take the measurements from the FPGA 330, and may apply a predetermined vector error model of the system, and then may calculate the difference in load impedance at the RF fundamental frequency of test to a desired target load impedance value, e.g., provided by the user. The desired target load impedance value may be specified by the user with software running on the controller 320. The vector-based error calculation may then be used to calculate a load-pull injected signal that may be fed to the FPGA 330. The FPGA 330 may relay the waveform data to the VSG 372 for onward transmission to the output port of the DUT 305. The load-pull signal may be transmitted synchronously with the input signal, e.g., using a shared trigger signal originating from the FPGA 330 and common clock frequency.

The FPGA 330 may provide trigger signals to the VSAs 380, 382, 384, and 386, e.g., to time-align the captures across the ADCs 332, 334, 336, and 338. The FPGA 330 may provide trigger signals to the VSGs 370 and 372, e.g., to time-align the playback of the waveform across the DACs 340 and 342. In some example embodiments, a delay of one or more of the trigger signals may be individually adjusted. This may result in both sources being frequency-, time-, and phase-coherent. This may initiate a second measurement process that may then, in turn, provide an updated waveform array to the FPGA 330 and then to the VSG 372. This process may carry on (or repeat) until the measurement system achieves the target impedance value.

The example system 300 described in FIG. 3 is a RF fundamental-frequency-only system with DC supplies. There are other possible arrangements in accordance with example embodiments that may allow for measurement and control of higher RF harmonic frequencies, DC measurements, and/or baseband measurements.

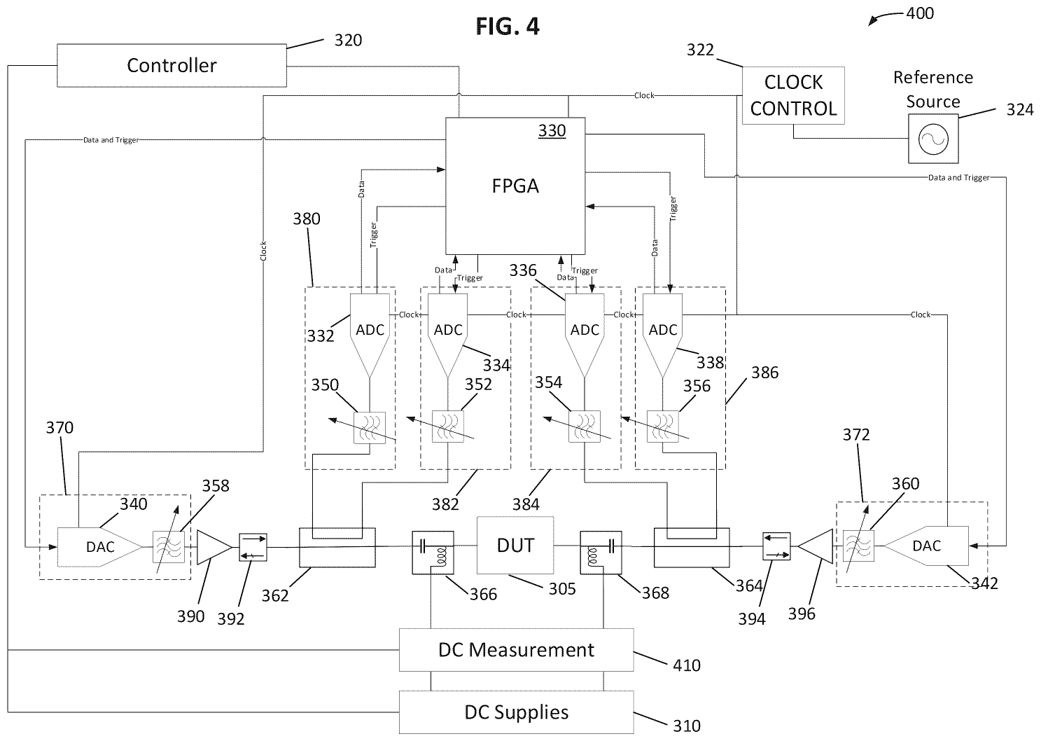

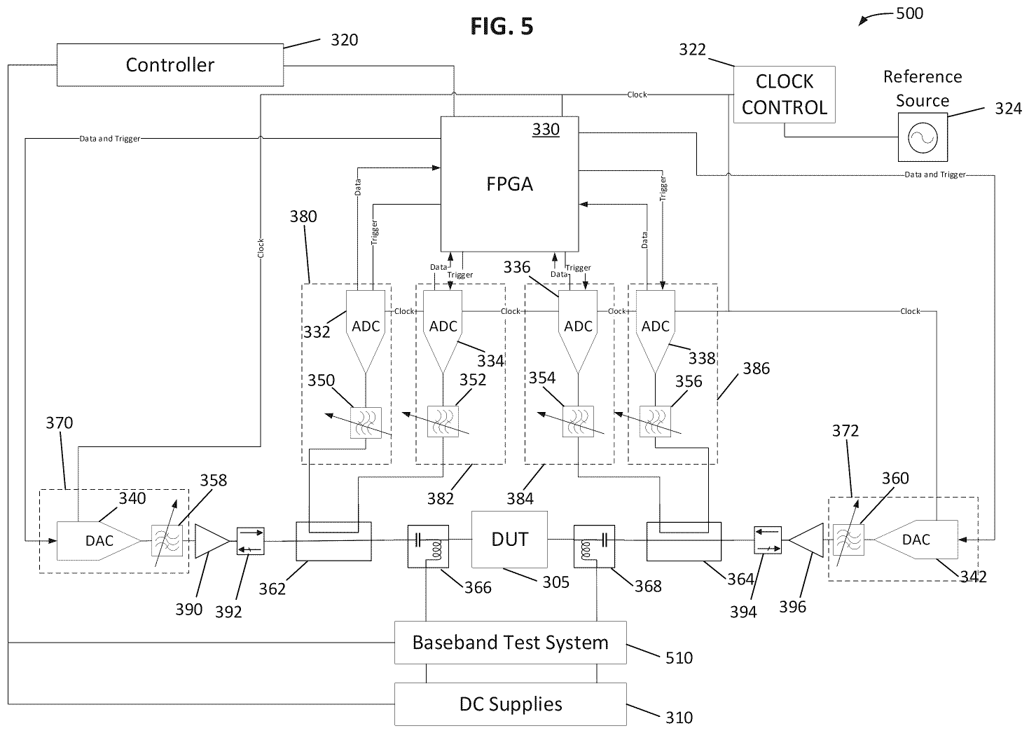

FIG. 4 is a schematic block diagram of a system according to an example embodiment of the present disclosure configured for a single RF fundamental frequency of test with DC measurement and DC supplies. FIG. 5 is a schematic block diagram of a system according to an example embodiment of the present disclosure configured for a single RF fundamental frequency of test with baseband frequency injection and measurement and DC supplies.

FIG. 4 depicts an example system 400 for active load-pull at the RF fundamental frequency only with a DC signal, which may further include a DC measurement block 410 between the DC signal supplies 310 and the DC bias tees 366 and 368 (see FIG. 3). FIG. 5 depicts an example system 500 for active load-pull at the RF fundamental frequency with an additional capability of baseband measurement and baseband load-pull, which includes DC and typically up to 100 MHz in frequency, shown as block 510 between the DC signal supplies 310 and the DC bias tees 366 and 368 (see FIG. 3).

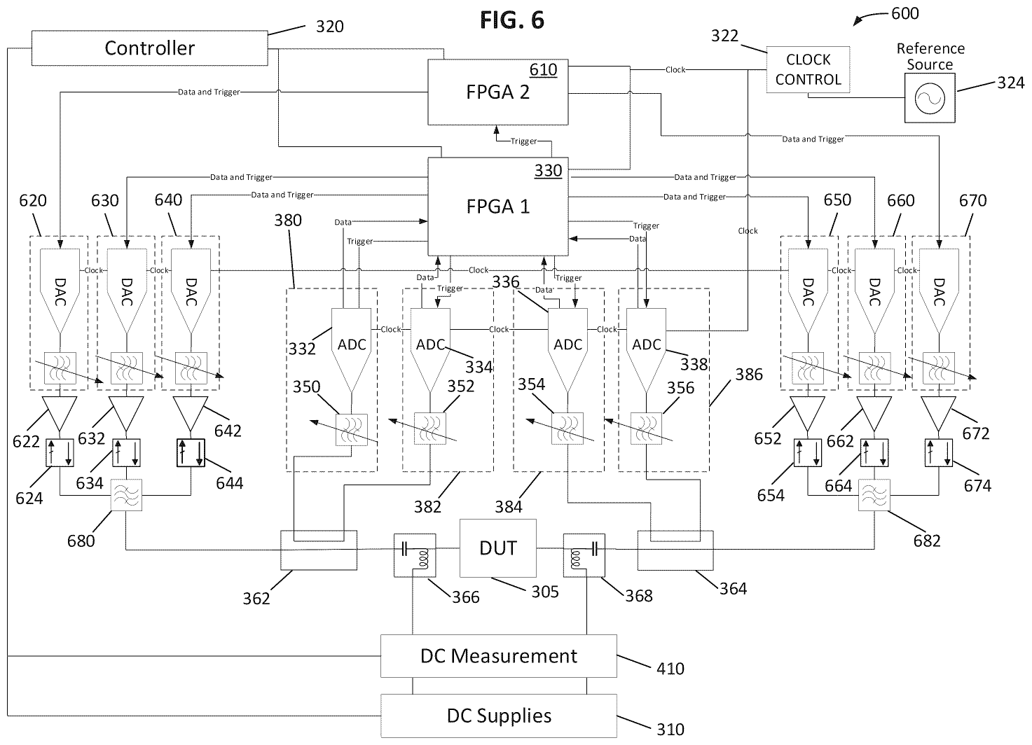

FIG. 6 is a schematic block diagram of a system according to an example embodiment of the present disclosure configured for multiple harmonics of the RF fundamental frequency of test at the input and output ports of the DUT with DC measurement and DC supplies.

FIG. 6 depicts an example system 600 for active load-pull at the RF fundamental frequency only with a DC signal, which may further include a DC measurement block 410 (see FIG. 4) between the DC signal supplies 310 and the DC bias tees 366 and 368 (see FIG. 3). FIG. 6 shows an example active load-pull system 600 configured to measure and impedance control up to three harmonic frequencies at the input and output ports of the DUT 305. VSGs 620, 630, 640, 650, 660, and 670, which may include respective DACs and signal-conditioning elements, may be individually configured, e.g., in terms of RF transmit frequency and/or RF amplitude. They may also each have individual respectively-input waveform arrays, e.g., originating from the controller 320 and fed into one or more FPGAs, e.g., FPGAs 330 and 610. An additional (or secondary) FPGA, for example, the FPGA 610, may be provided, e.g., due to limitations or requirements in terms of memory, digital signal processing functionality, and/or SERDES interfaces of the primary FPGA 330. The primary FPGA 330 may be the timing reference with a trigger signal that may be shared with the additional FPGA 610. Both FPGAs 330 and 610 may share a common clock frequency originating from the clock control 322. The active load-pull system 600 may configure the frequency of operation of the VSGs to be mirrored on both sides of the DUT 305. In this case, VSGs 620 and 650 may be configured to operate at the fundamental frequency of operation, VSGs 630 and 660 may be configured to operate at the second harmonic frequency of operation, and VSGs 640 and 670 may be configured to operate at the third harmonic frequency of operation. The operation of each VSG may be dependent on the user's desire to control the impedance at the corresponding harmonic frequency. Other harmonic frequencies or combinations of frequencies are possible. All the VSGs can be connected to amplifiers 622, 632, 642, 652, 662, and 672 and circulators 624, 634, 644, 654, 664, and 674. The multiple VSGs at the input and output ports may then be combined using signal-conditioning element 680 at the input side of the DUT 305 and signal-conditioning element 682 at the output side of the DUT 305. These combined signals may then be fed into the input port of DUT 305 through the RF coupler 362 and DC bias tee 366 and into the output port of DUT 305 through the RF coupler 364 and DC bias tee 368.

The VSAs 380, 382, 384, and 386 may all be configured to simultaneously measure the extracted traveling waves from the RF couplers 362 and 364. The controller 320 may configure the VSAs 380, 382, 384, and 386 to operate at the fundamental or higher harmonic frequencies, and request may digitized waveform captures from the FPGA 330, e.g., based on a common trigger signal that may be shared with the VSAs. The controller 320 may sequentially capture the RF waveforms directly at the RF fundamental frequency of test, as well as at the higher harmonic frequencies. The clock control 322 may feed in a common clock signal into the VSAs 380, 382, 384, and 386. This may ensure that the captures are synchronous in terms of frequency, time, and phase. The controller 320 may then apply a predetermined vector error model of the system at each captured frequency. The measurements may then be used to calculate the input and output impedances being presented to the DUT 305 at the fundamental and higher harmonic frequencies and compared against a set of target impedances defined by the user. The vector-based error of the measured impedances compared to the user defined target impedances may then be used to generate a new waveform array that may be fed into the FPGA 330 for onward transmission to the VSGs 620, 630, 640, 650, 660, and 670. This process may carry on until the measurement system achieves the target impedance, e.g., the user-defined target impedance.

The VSAs 380, 382, 384, and 386 may capture the measurements directly at the RF fundamental frequency of test and the higher harmonics in a sequential process. The digitized waveforms at each frequency may then be passed onto the FPGA, e.g., the FPGA 330. The FPGA may first apply a digital filter to filter out unwanted signals, then may digitally down-convert the frequency from RF to baseband, and then may digitally down-convert the sampling rate. The process of frequency down-conversion may be done by generating a digitally-based local oscillator (LO) within the FPGA at the same frequency of the captured data and feeding that into a digital mixer. The LO signal may be reconfigured to the frequency of the corresponding harmonic order to produce an output waveform at a baseband frequency. The phase of the LO signal at each frequency may be set to a fixed value relative to a high-frequency clock signal running at the maximum sample rate of the ADC. This may ensure that the frequency down-converted baseband waveform array will have a repeatable phase offset at the harmonics relative to the fundamental RF fundamental frequency of test. This may allow for the vector-based alignment of the fundamental and higher harmonic frequencies subject to applying a predetermined vector error model with harmonic phase calibration using a phase reference.

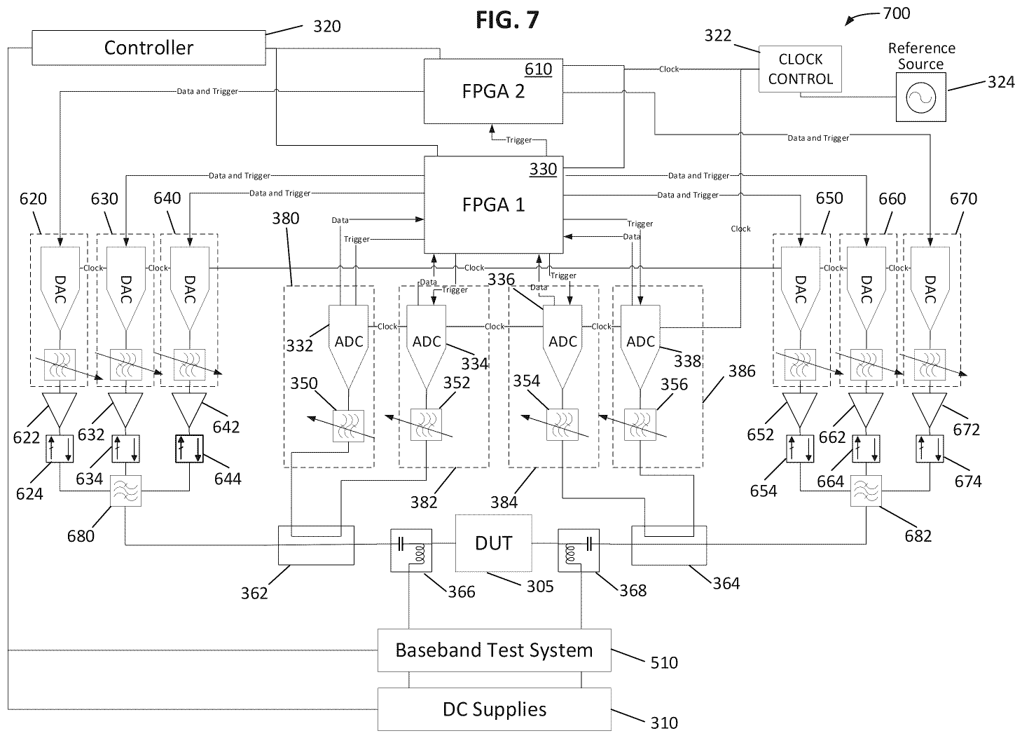

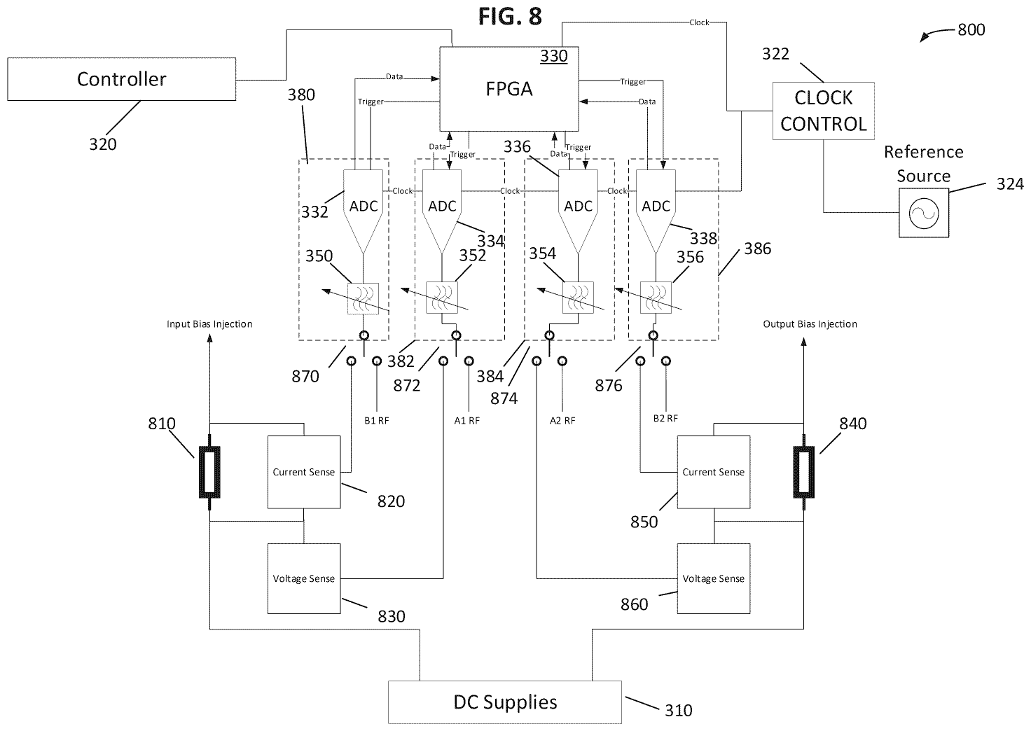

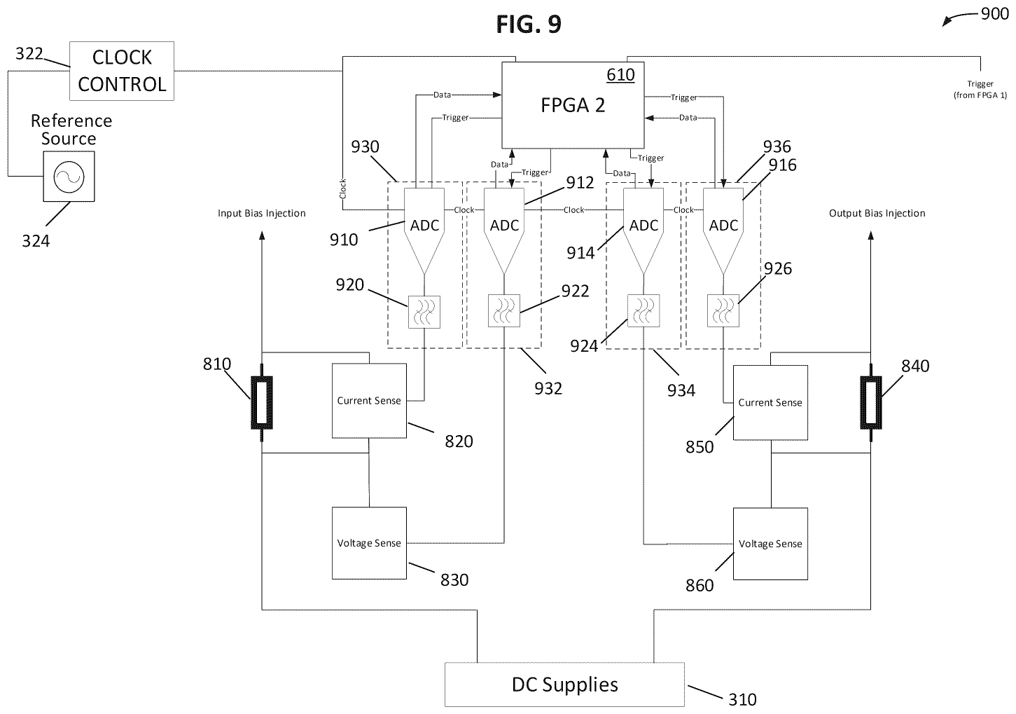

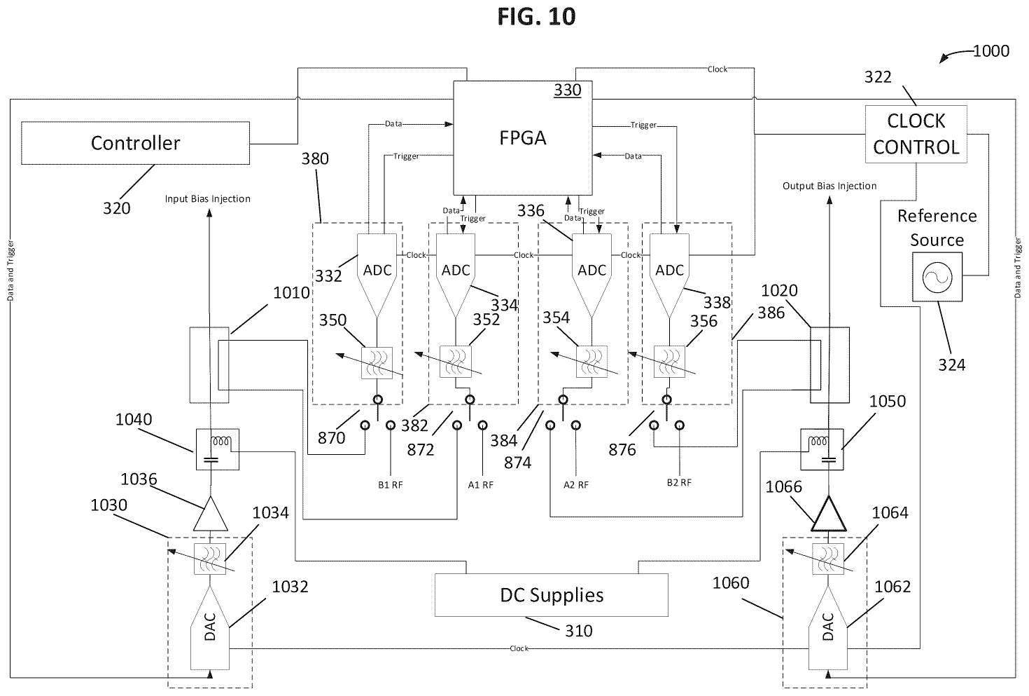

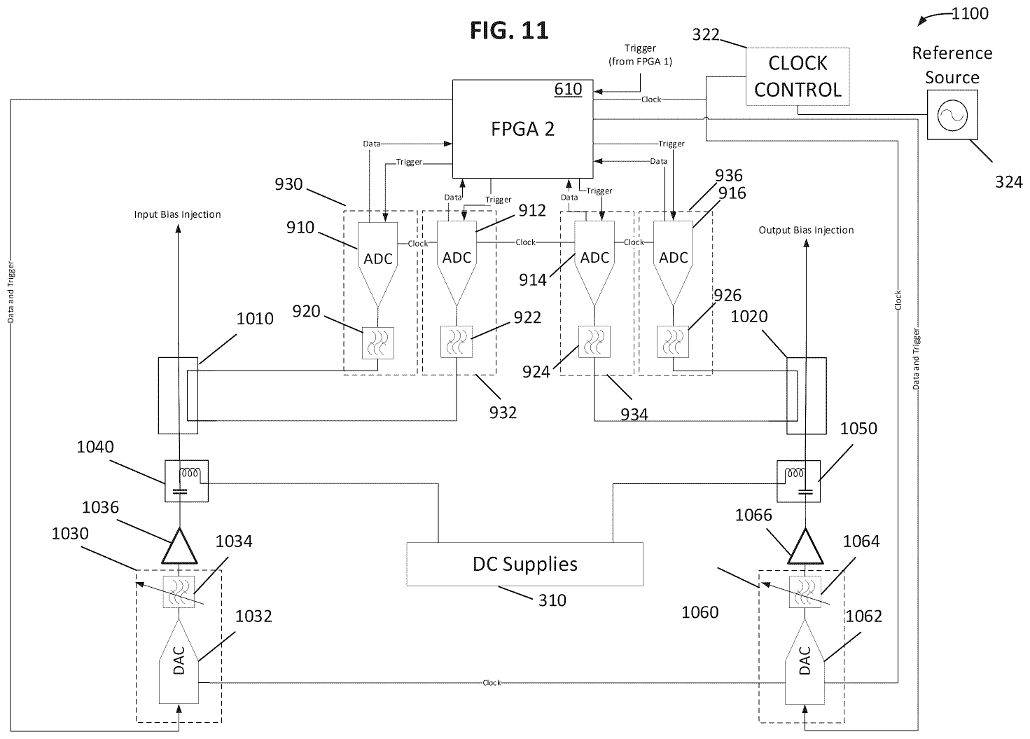

In FIGS. 7-11, some features in common with or repeated from previously-described FIGS. 3-6 may be reduced or omitted for convenience of explanation. FIG. 7 is a schematic block diagram of a portion of a system according to an example embodiment of the present disclosure. FIG. 8 is a schematic block diagram of a DC measurement portion of a system utilizing the RF measurement ADCs with signal conditioning elements according to an example embodiment of the present disclosure. FIG. 9 is a schematic block diagram of a DC measurement portion of a system utilizing a separate FPGA and set of ADCs with signal conditioning elements according to an example embodiment of the present disclosure. FIG. 10 is a schematic block diagram of a baseband test and measurement portion of a system utilizing the same FPGA as the RF test and measurement portion according to an example embodiment of the present disclosure. FIG. 11 is a schematic block diagram of a baseband test and measurement portion of a system utilizing a separate FPGA according to an example embodiment of the present disclosure.

FIG. 7 depicts an example system 700 for active load-pull at the RF fundamental with an additional capability of baseband measurement and baseband load-pull, which may be DC and typically up to 100 MHz in frequency shown as block 510 between the DC signal supplies 310 and the DC bias tees 366 and 368.

FIG. 8 depicts an example DC measurement subsystem 800. The example DC measurement subsystem 800 may be an example of the DC measurement block 410 of the example RF active load-pull system 400 illustrated in FIG. 4. FIG. 8 shows the DC part of an RF active load-pull system, with the RF parts omitted for convenience of explanation. The example DC measurement subsystem 800 may include two inputs that it may take from the DC supplies 310. The first supply source (e.g., from DC supplies 310) may be passed through a first resistive sense circuit 810 and the second first supply source (e.g., from DC supplies 310) may be passed through a second resistive sense circuit 840. The output of the first resistive sense circuit 810 may be connected to the DC bias tee 366, as shown in the example RF active load-pull system 400 of FIG. 4. The output of the second resistive sense circuit 840 may be connected to the DC bias tee 368, as shown in the example RF active load-pull system 400 of FIG. 4. The current and voltage sense circuits 820 and 830 may be respectively connected to each side of the first resistive sense circuit 810. The output of the current and voltage sense circuits 820 and 830 may be fed into respective broadband switches 870 and 872. The current and voltage sense circuits 850 and 860 may be respectively connected to each side of the second resistive sense circuit 840. The output of the current and voltage sense circuits 850 and 860 may be respectively fed into broadband switches 874 and 876. The broadband switches 870, 872, 874, and 876 may select between measuring the DC parameters from the current and voltage sense circuits 820, 830, 850, and 860 and the RF parameters extracted from the RF couplers 362 and 364 in the example active load-pull system 400 of FIG. 4. The signal output from the switches 870, 872, 874, and 876 may then be fed into the VSAs 380, 382, 384, and 386 for digitization and eventually onto the controller 320 via the FPGA 330. The controller 320 may apply a predetermined calibration factor to perform measurements at a calibrated reference plane. The controller 320 may apply a predetermined calibration factor to perform measurements at a calibrated reference plane.

FIG. 9 depicts an example DC measurement subsystem 900. The example DC measurement subsystem 900 may be an example of the DC measurement block 410 of the example RF active load-pull system 400 illustrated in FIG. 4. FIG. 9 shows the DC part of an RF active load-pull system, with the RF parts omitted for convenience of explanation. The example DC measurement subsystem 900 may include two inputs that it may take from the DC supplies 310. The first supply source (e.g., from DC supplies 310) may be passed through a first resistive sense circuit 810 and the second first supply source (e.g., from DC supplies 310) may be passed through a second resistive sense circuit 840. The first supply source (e.g., from DC supplies 310) may be passed through a first resistive sense circuit 810 and the second first supply source (e.g., from DC supplies 310) may be passed through a second resistive sense circuit 840. The output of the first resistive sense circuit 810 may be connected to the DC bias tee 366, as shown in the example RF active load-pull system 400 of FIG. 4. The output of the second resistive sense circuit 840 may be connected to the DC bias tee 368, as shown in the example RF active load-pull system 400 of FIG. 4. The current and voltage sense circuits 820 and 830 may be respectively connected to each side of the first resistive sense circuit 810. The output of the current and voltage sense circuits 820 and 830 may be fed into respective VSAs 930 and 932, which may respectively include ADCs 910, 912 and signal-conditioning elements 920, 922. The current and voltage sense circuits 850 and 860 are connected to both sides of the resistive sense circuit 840. The current and voltage sense circuits 850 and 860 may be respectively connected to each side of may be respectively connected to each side of the second resistive sense circuit 840. The output of the current and voltage sense circuits 850 and 860 may be fed into VSAs 934 and 936, which may respectively include ADCs 914, 916 and signal-conditioning elements 924, 926. The VSAs 930, 932, 934, and 936 may digitize the DC measurements. The digitized data may then be fed into the FPGA 610 for further processing. The data may then be passed onto the controller 320. The controller 320 may apply a predetermined calibration factor to perform measurements at the DUT reference plane.

FIG. 10 is a schematic block diagram of a baseband test and measurement portion of a system utilizing the same FPGA as the RF test and measurement portion according to an example embodiment of the present disclosure.

FIG. 10 depicts an example baseband test system 1000. The example baseband test system 1000 may be an example of the baseband test system block 510 of the example RF active load-pull system 500 illustrated in FIG. 5. FIG. 10 shows the baseband and DC and baseband part of the RF active load-pull system, with the RF parts omitted for convenience of explanation. The example baseband test system 1000 may include two DC inputs that it may take from the DC supplies 310. The first DC supply source, e.g., DC supplies 310, may be connected to a low-frequency DC bias tee 1040, and the second DC supply source, e.g., DC supplies 310, may be passed through a second low-frequency DC bias tee 1050. The example baseband test system 1000 may also include two high speed DACs 1032 and 1062, which may be connected to respective signal-conditioning elements 1034 and 1064. The DAC 1032 and signal-conditioning element 1034 can be described as a VSG 1030, and DAC 1062 and signal-conditioning element 1064 can be described as a 1060, and may each provide a respective signal output at baseband frequencies. The VSG 1030 may be connected to a low-frequency amplifier 1036, which may be connected to the DC bias tee 1040 to combine with the DC power provided by the DC supplies 310. The DC and baseband signal may then be fed into a low-frequency coupler 1010, which may extract the forward and reverse traveling waveforms at baseband frequencies. The signal may then be connected to the RF based DC bias tee 366, as in the example active load-pull system 500 of FIG. 5. The VSG 1060 may be connected to a low-frequency amplifier 1066, and then may be connected to the DC bias tee 1050 to combine with the DC power provided by the DC supplies 310. The DC and baseband signal may then be fed into a low-frequency coupler 1020, which may extract the forward and reverse traveling waveforms at baseband frequencies. The signal may then be connected to the RF based DC bias tee 368, as in the example active load-pull system 500 of FIG. 5. The extracted low-frequency traveling waves from the low-frequency couplers 1010 and 1020 may be fed into switches 870, 872, 874, and 876, as in the example of FIG. 8. The switches 870, 872, 874, and 876 may select between measuring the low-frequency traveling waves extracted from the low-frequency couplers 1010 and 1020 and the RF parameters extracted from the RF couplers 362 and 364 in the example active load-pull system 500 of FIG. 5. The signal output from the switches 870, 872, 874, and 876 may then be fed into the VSAs 380, 382, 384, and 386 for digitization, and eventually onto the controller 320, e.g., via the FPGA 330. The controller 320 may apply a predetermined calibration factor to perform measurements at a calibrated reference plane. The controller 320 may then apply a predetermined baseband frequency-based vector error model of the system. The measurements may then be used to calculate the input and output impedances being presented to the DUT 305 at baseband frequencies and compared against a set of target impedances, e.g., as defined by the user. The vector-based error of the measured impedances compared to the target impedances may then be used to generate a new waveform array that may be fed into the FPGA 330 for onward transmission to the VSGs 1030 and 1060. This process may carry on until the measurement system achieves the target impedance.

FIG. 11 depicts an example baseband test system 1100. The example baseband test system 1100 may be an example of the baseband test system block 510 of the example RF active load-pull system 500 illustrated in FIG. 5. FIG. 11 shows the baseband and DC and baseband part of an RF active load-pull system, with the RF parts omitted for convenience of explanation. The example baseband test system 1100 may include two DC inputs that it may take from the DC supplies 310. The first DC supply source, e.g., DC supplies 310, may be connected to a low-frequency DC bias tee 1040 and the second DC supply source, e.g., DC supplies 310, may be passed DC supply source, e.g., DC supplies 310, may be passed through a second low-frequency DC bias tee 1050. The example baseband test system 1100 may also include two high speed DACs 1032 and 1062, which may be connected to signal-conditioning elements 1034 and 1064. The DAC 1032 and signal-conditioning element 1034 can be described as a VSG 1030, and DAC 1062 and signal-conditioning element 1064 can be described as a 1060, and may each provide a respective signal output at baseband frequencies. The VSG 1030 may be connected to a low-frequency amplifier 1036, which may be connected to the DC bias tee 1040 to combine with the DC power provided by the DC supplies 310. The DC and baseband signal may then be fed into a low-frequency coupler 1010, which may extract the forward and reverse traveling waveforms at baseband frequencies. The signal may then be connected to the RF based DC bias tee 366, as in the example active load-pull system 500 of FIG. 5. The VSG 1060 may be connected to a low-frequency amplifier 1066, and then may be connected to the DC bias tee 1050 to combine with the DC power provided by the DC supplies 310. The DC and baseband signal may then be fed into a low-frequency coupler 1020, which may extract the forward and reverse traveling waveforms at baseband frequencies. The signal may then be connected to the RF based DC bias tee 368, as in the example active load-pull system 500 of FIG. 5. The extracted low-frequency traveling waves from the low-frequency couplers 1010 and 1020 are fed into VSAs 930, 932, 934, and 936 which may include ADCs 910, 912, 914, and 916 and signal-conditioning elements 920, 922, 924, and 926, as in the example of FIG. 9. The VSAs 930, 932, 934, and 936 may digitize the baseband measurements. The digitized data may then be fed into FPGA 610 for further processing. The data may then be passed onto the controller 320. The controller 320 may apply a predetermined frequency-based vector error model of the system. The measurements may then be used to calculate the input and output impedances being presented to the DUT 305 at baseband frequencies and compared against a set of target impedances, e.g., as defined by the user. The vector-based error of the measured impedances compared to the target impedances may then be used to generate a new waveform array that may be fed into the FPGA 330 for onward transmission to the VSGs 1030 and 1060. This process may carry on until the measurement system achieves the target impedance.

In the various example embodiments shown in FIG. 3 through FIG. 11, there can be one or more FPGAs, e.g., FPGAs 330 and 610, within the example active load-pull systems described in this disclosure. This could be due to limitations or requirements in processing capability or SERDES connections, as well as for possible further feature developments. Each FPGA could be connected to only ADCs or only DACs, or any combination of ADCs and DACs. The separation of digital signal processing features, such as digital filtering, digital frequency mixing, and DDC or DUC can be done within the FPGA or within the ADC or DAC. This could also apply to other features not mentioned here. The ADC and DACs can be housed within a single integrated circuit (IC), for example, to form a mixed signal front end (MXFE) chip, or may be spread across any combination of multiple ICs or circuitry. As an example, the ICs could only be ADCs or DACs.

The example systems described in FIG. 3 through FIG. 11 can also be supplemented with the use of passive tuners. Passive tuners can be positioned in the RF path at both the input and output ports of the DUT 305. The passive tuner can provide impedance tuning at the RF fundamental frequency of test and simultaneously at the higher harmonic frequencies. Passive tuners can also be placed in the baseband signal path at the input DC bias tee 366 and/or at the output DC bias tee 368 to present an impedance at baseband frequencies. For example, the tuner may be controlled by the user through the controller 320. The passive tuner may have a predetermined calibration to enable the user to set the impedance being presented to the DUT 305. The user may set the impedance of the passive tuner, e.g., via the controller 320. An active load-pull system according to an example embodiment of the present disclosure may support impedance tuning using just the passive tuner, using an active tuner, or using a combination of the two impedance tuning methods, which may be referred to as a “hybrid” load-pull. The method of load-pull may be selected by the user, and the process may be managed by the controller 320.

An example active load-pull system may also include the use of software to configure and control VSAs to measure signals to and from the DUT at the RF fundamental frequency of test and plurality of harmonics. This may allow for the characterization of the DUT, as well as the load-pull system, for example, measurements of the various impedances being presented to the input and output ports of the DUT at the RF fundamental frequency of test and plurality of harmonics using the aforementioned VSAs as receivers. The RF measurements may be extracted via directional couplers placed at the input and output ports of the DUT. The system's software may allow for vector-based calibration of the active load-pull system for measurements to be referenced to the input and output ports of the DUT. This may allow the system to measure DUT performance parameters such as output power, gain, and efficiency, as well as the system's impedances being presented to the DUT at both the input and output ports. The system's software may also allow the characterization of the system in terms of additional amplifier gains not previously defined and the system impedances prior to the commencement of measurements to the DUT. This process may be applicable to the fundamental RF fundamental frequency of test and harmonics, for example, if desired by the user, and may be termed as the “initialization process.” With the use of a RF phase reference, an example active load-pull system may be able to correlate the measurements done by RF fundamental frequency of test with the harmonic frequencies. This may enable time domain-based current and voltage measurements at the input and output ports of the DUT. Additionally, an example system may also be able to measure DC currents and voltages to allow for the calculation of DUT's efficiency of operation.

The VSAs may be software-controllable, e.g., in terms of amplitude control and/or frequency of measurement. The amplitude control, or from a user perspective the reference level setting of the receiver, may allow for the adjustment of the RF signal amplitude being fed into the ADC. This can be done in terms of applying attenuation or amplification of the RF measurement signal extracted from the couplers connected to the DUT. The VSAs may also have frequency-selective filter banks to isolate the desired RF frequency of measurement, such as RF fundamental frequency or the related harmonics from other unwanted signals at other frequencies. The software may be able to configure these parameters as the frequency of measurement is varied. For example, if the user desires, the software may be able to support the setting of multiple reference levels to enhance the dynamic range of power of the system, e.g., to beyond 60 dB of power range. As the ADC is capable of measuring directly at the RF fundamental frequency of test, an example active load-pull system may also be capable of maintaining a consistent relative phase relationship of multiple captures as it switches from one frequency to another. This feature is otherwise known as “phase memory.” In the event the user has set up the system for time domain measurements, the phase memory feature may maintain the phase relationship between the fundamental frequency of test and harmonics. This may then allow for a single time calibration of the phase reference for time domain measurements.

An example active load-pull system software may also be able to control the two or more VSGs that are frequency-locked, phase-coherent, and/or time-synchronized. The first and second VSGs may be set to operate at the RF fundamental frequency of test, and may be injected at the input or output ports of the DUT. Additional VSGs can be set to operate at harmonic frequencies based at the RF fundamental frequency of test. The VSGs may be capable of transmitting CW, pulsed RF, and/or arbitrary signals that may vary in amplitude and frequency over time. The VSGs can be individually set in terms of power and phase at the calibrated reference plane using the vector calibration and system initialization. In the event of multiple VSGs being required to be configured, the process can be done simultaneously or sequentially, for example, dependent on the user's preference.

An example active load-pull system may allow the user to measure and set impedances presented to the input and output ports of the DUT. The active load-pull software may take vector corrected measurements extracted from the input and output couplers to calculate the impedances presented to the input and output ports of the DUT at the RF fundamental frequency of test plus plurality of harmonics. The process of measurements at each frequency can be done sequentially or in parallel. The same measurements may also be used to calculate various ratios of the forward and reverse traveling waves to describe the system impedances being presented to the input and output ports of the DUT at the RF fundamental frequency of test plus plurality of harmonics. The active load-pull system software may also allow the user to set and control the impedances being presented to the input and output ports of the DUT at the RF fundamental frequency of test plus plurality of harmonics. Once the active load-pull system has successfully presented the user set impedances, the software may provide updated measurements of various performance metrics, such as output power, gain, and/or efficiency of the DUT. The active load-pull software may conduct a sweep of multiple impedances at the input and output ports of the DUT at the RF fundamental frequency of test plus plurality of harmonics that are set and measured sequentially. The active load-pull software may also embed additional sweep parameters such as the input RF signal power at the RF fundamental frequency of test.

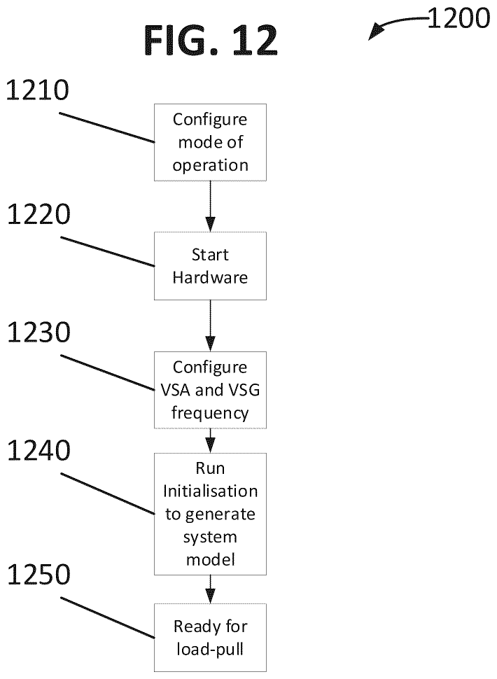

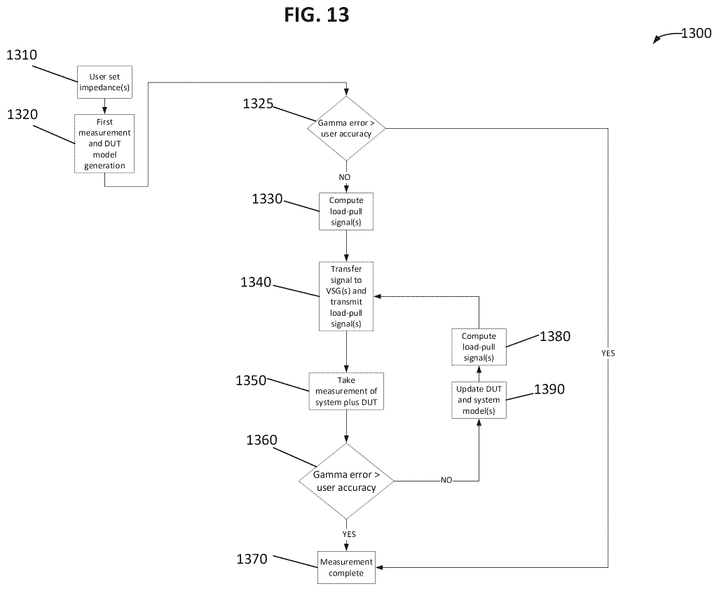

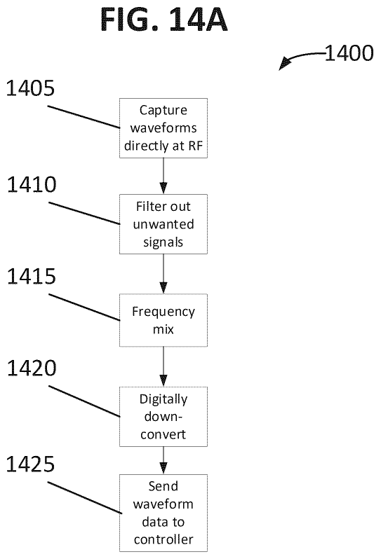

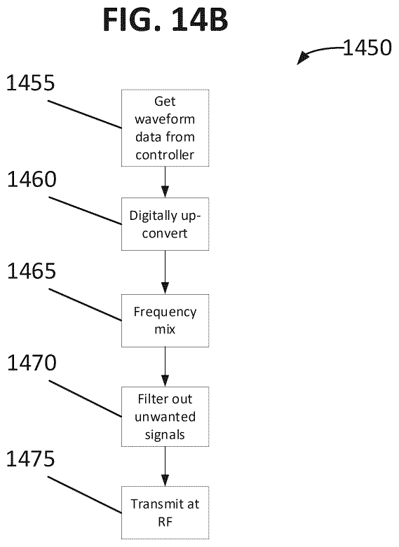

FIG. 12 is a flow chart outlining the process of load pull with a check condition comparing the measured impedance with the user set impedance. FIG. 13 is a flow chart of the initialization process to determine the system model. FIG. 14A and FIG. 14B are flow charts of the digital processes being applied between the computer controller and the high sampling rate ADCs and DACs.

Prior to the process of active load-pull, the software may generate a system model at the RF fundamental frequency of test, plus at a plurality of harmonics. This is described in reference to the example method 1200 of FIG. 12. In the example method 1200, the user may first start configuring the mode of operation, as shown in block 1210. This can be, for example, in a CW mode, an RF pulsed mode, or a modulated mode. In block 1220, the user may then start the hardware, and this may initiate the software, as shown in block 1230, to configure and control the various VSAs and VSGs to operate at the RF fundamental frequency of test plus a plurality of harmonics. The user may then connect the system, e.g., in a through-configuration, and may run the initialization, as shown in block 1240. The initialization process may then sequentially inject signals using the plurality of VSGs and measure the system at each stage. This may then form a system model that describes gain present for each configured VSG and the system impedance at the corresponding port of the DUT and frequency of measurement. Once this is complete, as shown in block 1250, the system may be ready for active load-pull.

An example active load-pull system software may allow the user to set and control impedances presented to the input and output ports of the DUT at the RF fundamental frequency of test plus a plurality of harmonics. A process of active load-pull is described in reference to the example method 1300 of FIG. 13. In the example method 1300, the process may be first initiated by the user's entering an impedance at the RF fundamental frequency of test in block 1310 and initiating the measurement process. The process of impedance control may then be initiated by first making a measurement of the DUT with the system in its current state, e.g., in terms of the input power level and the current system impedances being presented to the input and output ports of the DUT and at the RF fundamental frequency of test. This is described in block 1320, where the method of load pull may generate a model of the system and the DUT using measurement data of the current system state and calculating the vector error of the current impedance state against the user set system impedance at a single frequency. The vector error of the current impedance state may be first assessed against a user-set impedance accuracy tolerance, as shown in block 1325. If the vector error is above the tolerance level specified (“NO” at block 1325), the vector error of the current impedance may then form the information to calculate the power and phase of the signal to be injected into the DUT to achieve the user-set impedance target, as shown in block 1330. In block 1340, the software may then transfer the settings to the VSG to adjust the signal amplitude based on prior information of the system and based on the initialization measurements and vector calibration of the system. The software may then configure the VSG assigned to control the corresponding signal to be injected or updated at the input or output port of the DUT and frequency component. The software may then execute the updated signal configured in the corresponding VSG while maintaining phase coherence and being synchronous in time with the one or more of the other VSGs operating at the same time. In block 1350, the software may then re-measure the input and output ports of the DUT, and in block 1360, may re-assess the vector error in the newly updated current state with the user-set impedance target. If the measured impedance vector error is within the accuracy tolerance specified by the user (“YES” at block 1360), the software may stop any further updates and notify the user. as shown in block 1370. If the newly-updated vector error is still outside of the user specified accuracy tolerance (“NO” at block 1360), the active load-pull system may go through a second iteration and update the system and DUT models in block 1380, and then may compute a new load pull signal. as shown in block 1390, and may provide the VSG with an updated signal setting in block 1340 and carry on until the system has successfully achieved the user-set impedance, or may stop at a user-specified maximum number of iterations.

An example active load-pull system software may allow the user to set and control one or more impedances to be presented to the input and output ports of the DUT at the RF fundamental frequency of test plus plurality of harmonics. The process of measurement and impedance control may be done in parallel or in a sequence. The process of load-pull may continue until all the impedance error vectors of the user-set ports and frequencies have met their accuracy tolerance levels, or until the system has taken up the user-specified maximum number of iterations.

An example active load-pull system software may utilize a complete set of traveling wave information at the RF fundamental frequency of test plus a plurality of harmonics to determine the updated injection signal. During this process of measurement, the software impedance control algorithm may calculate the various ratios of S₁₁, S₂₁, S₁₂, and S₂₂ of the DUT based on the collected measurements to construct a model of the DUT. For example, in a two-port network, scattering parameters S₁₁, S₂₁, S₁₂, and S₂₂ may define how signals behave at the input and output ports. S₁₁ and S₂₂ may indicate how much of the signal is reflected back at each port (e.g., reflection coefficients), while S₂₁ and S₁₂ may describe how signals pass through the network from one port to the other (e.g., transmission coefficients). These parameters may be used for analyzing the frequency-dependent performance of the DUT.

In parallel, the software algorithm may also calculate the various load-pull system parameters to describe the impedance environment being presented to the DUT at the RF fundamental frequency of test plus harmonics. The local model of the DUT may then be used to calculate the expected output value (e.g., transmitted wave) of b2 based on the input signal (e.g., incident wave) a1 and the target impedance, for example, as specified by the user. Based on this calculation, the value of the injected signal may be determined, and the power and phase settings of the injected signal may then be sent to the VSG for transmission. An example active load-pull system may also allow for the determination of the injected signal to be done as a function of b2 and the impedance presented by the system. This may also lead to the calculation of a power and phase setting that may be sent to the VSG for transmission. After the VSG has transmitted the updated signal for load-pull, a measurement may be done to calculate the impedance vector error and assess the system's performance with the user-specified accuracy tolerance.

Example software may individually and independently apply the load-pull algorithm to all impedance control loops at both the input and output ports of the DUT and at the RF fundamental frequency of test plus plurality of harmonics. The calculation and iterative process for each load-pull control loop may be done in parallel after the process of measurement has been completed. Each associated VSG may be sent the configuration information, and the new signals may be applied simultaneously.

An example active load-pull system software may model the system and DUT at the RF fundamental frequency of test plus harmonics. The individual measurements may be fitted within a finite impulse response (FIR) filter topology with a resolution bandwidth that may be linked to the order of the filter or number of filter coefficients. The load-pull calculation may be applied using the FIR filter-based descriptions of the system and DUT, the resolution of which may be independently defined by the order of the filter or number of filter coefficients. An example active load-pull software may configure the FIR filter order as a function of the bandwidth of load-pull as configured by the user, which may be independent to the resolution bandwidth of the injected signal or the resolution bandwidth of the measured waveforms. FIR filters may be assigned to describe the system and DUT behavior at the input and output ports of the DUT and at the RF fundamental frequency of test plus harmonics. The calculation and iterative process for each load-pull control loop may be done in parallel after the process of measurement has been completed. Each associated VSG may be sent the configuration information, and the new signals may be applied simultaneously.

An example active load-pull system software may model the system and DUT at baseband frequencies. The individual measurements may be fitted within a finite impulse response (FIR) filter topology with a resolution bandwidth that may be linked to the order of the filter or number of filter coefficients. The load-pull calculation may be applied using the FIR filter-based descriptions of the system and DUT, the resolution of which may be independently defined by the order of the filter or number of filter coefficients. An example active load-pull software may configure the FIR filter order as a function of the bandwidth of load-pull as configured by the user, which may be independent to the resolution bandwidth of the injected signal or the resolution bandwidth of the measured waveforms. FIR filters may be assigned to describe the system and DUT behavior at the input and output ports of the DUT and at the RF fundamental frequency of test plus harmonics. The calculation and iterative process for each load-pull control loop may be done in parallel after the process of measurement has been completed. Each associated VSG may be sent the configuration information, and the new signals may be applied simultaneously.

An example active load-pull system software may enable direct feedback of the vector error-corrected measurements to the VSGs to self-adjust the signal based on an impedance error vector calculation of the measurement with a user-specified target. The signal adjustment may be done in magnitude and in phase, as well as over a user-specified bandwidth of operation. The user can specify impedance targets at the RF fundamental frequency of test plus plurality of harmonics and baseband frequencies.

FIG. 14A is a flowchart of an example method 1400 for digitizing the RF waveform and transferring the data to the computer controller. When setting up the VSAs, the FPGAs may send a trigger signal to the ADC to capture at the RF fundamental frequency of test for a specified duration of time from the ADC. This is shown in block 1405. The digitized waveform data may then be passed through a digital filter in block 1410 to filter out any other unwanted signals. The waveform capture may then be digitally mixed from the RF fundamental frequency of test to baseband frequency using an internally derived LO signal in block 1415. The baseband frequency array may then be digitally down-converted (DDC) to a lower sample rate in block 1420, and the waveform may then be temporarily stored, e.g., in RAM. The waveform capture may then be sent to the controller for further post-processing and analysis in block 1425.

FIG. 14B is a flowchart of an example method 1450 for the computer controller sending waveform data to the VSG for transmission at RF fundamental frequency of test or harmonics. In block 1455, the waveform data may be transferred to the FPGA. The waveform array of data, initially operating at baseband, may then go through a process of digital up-conversion (DUC), as shown in block 1460, to the DACs baseband sample rate. Then the waveform array may be digitally mixed with an internally derived high-frequency LO to the frequency of test. This is shown in block 1465. The high-frequency array may then be passed through a filter to remove any unwanted digitally-derived frequency products and for any further frequency-based equalization of the array, as shown in block 1470. Finally, the waveform may be transmitted out of the DAC at the RF fundamental frequency of test or harmonics, as shown in block 1475.

The following are sections in accordance with at least one embodiment of the present disclosure:

Clause 1: A system for active load-pull measurements of a semiconductor device under test (DUT), including: a controller, a primary field-programmable gate array (FPGA) operably connected to the controller, the primary FPGA being configured to control and collect waveform data from a first plurality of vector signal analyzers (VSAs), each of the first plurality of VSAs including a respective analog-to-digital converter (ADC) connected to a respective ADC signal-conditioning circuit configured to directly capture radio frequency (RF) measurements of an input signal at an RF fundamental frequency of test and a plurality of harmonics, each ADC signal-conditioning circuit being configured to alter a signal amplitude and to isolate a wanted RF frequency of measurement at either the RF fundamental frequency of test or one of the plurality of harmonics to be received by its corresponding ADC, first and second couplers respectively configured to generate the input signal for each ADC by extracting forward and reverse traveling waves at RF respectively from input and output ports of the DUT, wherein the first plurality of VSAs are configured to capture the input signals directly at the RF fundamental frequency of test or the plurality harmonics over a user-specified frequency bandwidth centered at the RF fundamental frequency of test or one of the plurality harmonics and for a duration of time specified by a user, wherein the FPGA is further configured to control and to send waveform data to a first plurality of vector signal generators (VSGs) respectively including digital-to-analog converters (DACs), each DAC being configured to transmit a respective signal directly at the RF fundamental frequency of test or at one of the plurality of harmonics, each DAC being respectively connected to a DAC signal-conditioning circuit configured to alter a signal amplitude of the signal transmitted from the DAC and filter out unwanted signals, the first plurality of VSGs being configured to transmit respective vector signals directly at the RF fundamental frequency of test or at one of the plurality of harmonics over a user-specified frequency bandwidth centered at the RF fundamental frequency of test or at one of the plurality of harmonics and a duration of time determined by the user, a first amplifier configured to receive a first RF vector signal from a first of the first plurality of VSGs and generate a first amplified RF signal, the first RF vector signal being generated from a forward traveling wave, a second amplifier configured to receive a second RF vector signal from a second of the first plurality of VSGs and generate a second amplified RF signal, the second RF vector signal being generated from a reverse traveling wave, a first circulator configured to: receive the first amplified RF signal from the first amplifier, and transmit the first amplified RF signal to the first coupler, the first coupler being further configured to transmit the first amplified RF signal to the DUT, a second circulator configured to: receive the second amplified RF signal from the second amplifier, and transmit the second amplified RF signal to the second coupler, the second coupler being further configured to transmit the second amplified RF signal to the DUT, a reference generator source configured to provide a waveform connected to a clock control, the clock control being configured to output a plurality of clock signals to the primary FPGA, the ADCs, and the DACs, the clock control signal being configured for synchronizing and triggering measurements for the first plurality of VSAs, the first and second vector signals transmitted to the first plurality of VSGs being synchronized by the clock signal, wherein the controller is further configured to vector error-correct the captured waveform data and the transmitted RF waveforms to a user-specified calibrated reference plane for measurement of DUT parameters at the RF fundamental frequency of test and the plurality of harmonics and of system impedances at the input and output ports of the DUT at the RF fundamental frequency of test and the plurality of harmonics, the waveform measurement data being used to calculate an injection signal at a user-specified DUT port and frequency to alter the impedance at the DUT, the injection signal being synchronized with the input signal to measure a new system state, wherein the measurement at the user-specified calibrated reference plane and frequency is checked against a user-specified impedance setting and user-specified accuracy tolerance, and wherein, in response to the measurement not being within the user-specified accuracy tolerance, a new injection signal is calculated at the corresponding user-specified calibrated reference plane and user-specified frequency bandwidth, and the controller repeats testing until the user-specified accuracy the user-specified accuracy tolerance is reached or when a maximum number of attempts have been made.

Clause 2: The system of clause 1, further including: a secondary FPGA operably connected to the controller, the secondary FPGA being connected to a second plurality of VSAs for measurement and impedance control of a second plurality of harmonics, the secondary FPGA being time-synchronized and time-aligned with the primary FPGA via a clock signal frequency and a trigger signal, the secondary FPGA being configured to control and to send waveform data to a second plurality of vector signal generators (VSGs) respectively including digital-to-analog converters (DACs), each DAC being configured to transmit a respective signal directly at the RF fundamental frequency of test or at one of the plurality of harmonics, each DAC being respectively connected to a DAC signal-conditioning circuit configured to alter a signal amplitude of the signal transmitted from the DAC and filter out unwanted signals, the second plurality of VSGs being configured to transmit respective vector signals directly at the RF fundamental frequency of test or at the one of the plurality of harmonics over the user-specified frequency bandwidth centered at the RF fundamental frequency of test or at the one of the plurality of harmonics and for the duration of time determined by the user, wherein the plurality of injected signals at the RF fundamental frequency of test and the plurality of harmonics are combined at both the input and output ports of the DUT prior to being received by RF couplers to generate a vector error-corrected multi-harmonic signal to be received at input and output ports of the DUT.

Clause 3: The system of clause 1, further including: one or more direct current (DC) power supplies, and DC measurement circuitry operably connected to the one or more DC power supplies and to the primary FPGA, wherein the DC measurement circuitry is configured to use the first plurality of VSAs with their respective ADCs to capture voltage and current at DC, wherein ADC input waveforms are provided by the ADC signal-conditioning circuits that alter the amplitude of input waveform and remove unwanted frequencies within each input waveform, wherein an input signal to each ADC signal-conditioning circuit is provided by voltage and current sense circuits, and is fed a signal from a sense resistor respectively placed at input or output ports of the DUT, and wherein captured voltage and current waveforms are error-corrected to provide measurements at a common reference plane of RF measurements.

Clause 4: The system of clause 1, further including a plurality of DC bias tees respectively configured to supply DC power to input or output ports of a DUT.

Clause 5: The system of clause 1, further including: a baseband test system configured to provide active load-pull of a DUT, and baseband measurement circuitry including the first plurality of VSAs with respective ADCs to capture traveling waves collected at baseband frequencies and connected to the FPGA, wherein an ADC input waveform is provided by each ADC signal-conditioning circuit that alter amplitude of the input waveform and remove unwanted frequencies within the input waveform, and wherein the input signal to each signal conditioning circuits is provided by one of low-frequency couplers respectively at input and output ports of the DUT, the low-frequency couplers being configured to extract forward and reverse traveling waves measured at baseband frequencies.

Clause 6: The system of clause 1, wherein: baseband active load-pull is applied to input and output ports of DUT, and transmitted baseband signals from the first plurality of VSGs are sent to amplifiers connected to respective low-frequency DC bias tees that combine DC power provided by one or more direct current (DC) power supplies with a respective baseband signal provided by a respective VSG, an amplified signal is then passed through a low-frequency coupler and then combined with an RF signal via the DC bias tees, and signal amplitudes are vector error-corrected to present a desired signal at an RF-calibrated reference plane.

Clause 7: The system of clause 1, wherein: the first plurality of VSAs with ADCs are connected to a main FPGA for baseband waveform capture, or a second plurality of VSAs with ADCs are connected to a secondary FPGA for baseband waveform capture.

Clause 8: The system of clause 1, wherein: the first plurality of VSGs with DACs are connected to a main FPGA for baseband waveform transmission, or a second plurality of VSGs with DACs are connected to a secondary FPGA for baseband waveform transmission.

Clause 9: The system of clause 1, wherein a desired impedance and RF fundamental frequency of test are defined by a user before configuration information is provided.

Clause 10: The system of clause 1, wherein a desired impedance is set at an RF fundamental frequency of test and plurality of harmonics and baseband frequencies simultaneously by a user before configuration information is provided.

Clause 11: The system of clause 1, wherein: at least one of the ADCs captures waveforms over a user-specified bandwidth centered at a user-specified RF fundamental frequency of test or plurality of harmonics, a digitally-converted RF waveform is filtered to remove unwanted signals, a filtered signal is frequency-converted and then digitally down-converted to a lower sample clock rate, waveforms are then transferred to a controller for further processing, at least one of the DACs transmits waveforms over bandwidth at a user specified RF fundamental frequency of test or harmonics, where the controller transfers the waveform data to the primary FPGA and onwards to the at least one of the DACs at a sample rate based on a user-specified load-pull bandwidth requirement, and the waveform data is digitally up-converted to a sample rate of DAC output, then frequency-converted to the RF fundamental frequency of test or one of the plurality of harmonics before conversion into an analog domain output signal.

Clause 12: The system of clause 1, wherein filtering, frequency down-conversion, and digital down-conversion of captured waveform data in a digital domain is performed within the primary FPGA or within one of the ADCs.

Clause 13: The system of clause 1 wherein filtering, digital up-conversion, and frequency up-conversion of transmitted waveform data in a digital domain is performed within the primary FPGA or within one of the DACs.

Clause 14: A method for a system for active load-pull measurements of a semiconductor device under test (DUT), the method including: configuring and controlling a first plurality of vector signal analyzers (VSAs) to directly capture and to digitize measurements at input and output ports of the DUT at radio frequency (RF) fundamental frequency of test and at a plurality of harmonics, wherein each VSA respectively includes a high sample rate-based analog-to-digital converter (ADC) that directly captures waveforms at RF fundamental frequency of test and are connected to a respective ADC signal-conditioning circuit that control an amplitude of incoming signal and filter out unwanted frequency components, the VSAs output a digitized signal to a primary field-programmable gate array (FPGA) and send waveform data to a controller, the controller generates and transmits waveform data to the primary FPGA to output digitized data to a first plurality of vector signal generators (VSGs), controlling the first plurality of VSGs to directly inject signals at input and output ports of the DUT at the RF fundamental frequency of test and the plurality of harmonics, wherein the first plurality of VSGs respectively include high sample rate DACs that directly transmit signals at RF frequencies and are respectively connected to DAC signal-conditioning circuits that control an amplitude of an output signal and filter out unwanted frequency components, the first plurality of VSGs transmit injected signal through RF couplers and direct current (DC) bias, both placed at respective input and output ports of the DUT, the RF couplers pass through the transmitted injected signal while extracting forward and reverse traveling waves to feed into the first plurality of VSAs, the controller configures a first of the first plurality of VSGs connected to the input port of the DUT and at RF fundamental frequency of test to inject a signal, the controller assesses an impedance of the system at the RF fundamental frequency of test and the plurality of harmonics at both the input and the output ports of the DUT against a user-specified series of impedance targets at the RF fundamental frequency of tests and the plurality of harmonics at the input and the output ports of the DUT to a user-specified level of accuracy, in response to not meeting one of the user-specified series of impedance targets, the controller calculates a magnitude and a phase of an injected signal required to present to the DUT with the one of the user-specified series of impedance targets, and configures one of the first plurality of VSGs at the input or the output port of the DUT at the RF fundamental frequency of test or one of the plurality of harmonics, and the controller repeats a measurement to assess a newly-updated impedance being presented to the DUT, and in response to the repeated measurement not meeting a user-specified impedance target, calculates a new injected signal, and in response to the repeated measurement meeting the user-specified impedance target proceeds to completion of a measurement process.

Clause 15: The method of clause 14, wherein: a digitized capture by one of the first plurality of VSAs at the RF fundamental frequency of test or one of the plurality of harmonics is filtered, frequency-converted, and digitally down-converted to a sample rate based on a user-specified load-pull bandwidth for onward transmission of a digitized waveform from the primary FPGA to the controller, and the controller provides waveform data of one or more injected signals at one or more of the RF fundamental frequency of test or one of the plurality of harmonics at the input and output ports of the DUT at a sample rate based on user specified load-pull bandwidth to the primary FPGA for digital up-conversion to a sample rate of at least one of the DACs, and digital frequency-converted to the one or more of the RF fundamental frequency of test or one of the plurality of harmonics and filtering of unwanted signals to be transmitted out of the at least one of the DACs.

Clause 16: The method of clause 14, wherein digital functions of digital down-conversion, digital up-conversion, frequency mixing, and digital filtering are performed in a FPGA or in an associated ADC or DAC.

Clause 17: The method of clause 14, wherein: a software stored in a non-transitory computer-readable medium includes instructions that, when executed, cause one or more processors to: utilize a pre-determined system model that is vector error-corrected at the RF fundamental frequency of test and the plurality of harmonics, generate a model of the DUT to describe a behavior of the DUT as a function of an injected input signal, measure forward and reverse traveling waves at input and output ports of the DUT, and calculate a correction injected signal to actively load-pull the DUT at a user-specified input or output port of the DUT and frequency that is based on a user target, a system model, or a DUT model, and an injected signal for active load-pull is vector error-corrected to a calibrated reference plane.

Clause 18: The method of clause 14, further including: determining a system model by injecting signals using the VSGs at the RF fundamental frequency of test and the plurality of harmonics at the input and output ports of the DUT connected as a through configuration, the VSGs transmit signals through amplifiers, circulators, couplers, and DC bias tees, and error vector-correcting measurements at the RF fundamental frequency of test and the plurality of harmonics using the determined system model.

Clause 19: The method of clause 14, wherein: a predetermined system model that is vector error-corrected at the RF fundamental frequency of test and the plurality of harmonics and a DUT model as a function on an input signal are described over frequency using finite impulse response (FIR) filters, and a resolution bandwidth of the input signal is determined as a function of captured signal bandwidth divided by a filter order.

Clause 20: The method of clause 14, wherein: a resolution bandwidth of a received signal is described by a FIR filter used to describe a system model and DUT model, and the resolution bandwidth of the received signal is determined to be less than, similar to, equal to, or greater than a resolution bandwidth of a user-selected input signal.

Clause 21: The method of clause 14, wherein a process of active load-pull applies at the RF fundamental frequency of test and the plurality of harmonics at the input and output ports of the DUT in parallel or in a sequential manner.

Clause 22: The method of clause 14, wherein the method is process applied at baseband frequencies at the input and output ports of the DUT.

Clause 23: The method of clause 14, wherein: a respective passive tuner at each of an input or an output port of a DUT applies an impedance at the RF fundamental frequency of test and the plurality of harmonics, and an impedance of each passive tuner can be set at a fixed setting or can be varied during an iterative process at the RF fundamental frequency of test or at least one of the plurality of harmonics.

Systems and software, e.g., implemented on a non-transitory computer-readable medium, for performing the methods discussed herein are also within the scope of embodiments of the present disclosure.

Embodiments of the present disclosure may thus utilize a special purpose or general-purpose computing system including computer hardware, such as, for example, one or more processors and system memory. Embodiments within the scope of the present disclosure also include physical and other computer-readable media for carrying or storing computer-executable instructions and/or data structures, including applications, tables, data, libraries, or other modules used to execute particular functions or direct selection or execution of other modules. Such computer-readable media can be any available media that can be accessed by a general purpose or special purpose computer system. Computer-readable media that store computer-executable instructions (or software instructions) are physical storage media. Computer-readable media that carry computer-executable instructions are transmission media. Thus, by way of example, and not limitation, embodiments of the present disclosure can include at least two distinctly different kinds of computer-readable media, namely physical storage media or transmission media. Combinations of physical storage media and transmission media should also be included within the scope of computer-readable media.

Both physical storage media and transmission media may be used temporarily store or carry software instructions in the form of computer readable program code that allows performance of embodiments of the present disclosure. Physical storage media may further be used to persistently or permanently store such software instructions. Examples of physical storage media include physical memory (e.g., RAM, ROM, EPROM, EEPROM, etc.), optical disk storage (e.g., CD, DVD, HDDVD, Blu-ray, etc.), storage devices (e.g., magnetic disk storage, tape storage, diskette, etc.), flash or other solid-state storage or memory, or any other non-transmission medium which can be used to store program code in the form of computer-executable instructions or data structures and which can be accessed by a general purpose or special purpose computer, whether such program code is stored as or in software, hardware, firmware, or combinations thereof.

A “network” or “communications network” may generally be defined as one or more data links that enable the transport of electronic data between computer systems and/or modules, engines, and/or other electronic devices. When information is transferred or provided over a communication network or another communications connection (either hardwired, wireless, or a combination of hardwired or wireless) to a computing device, the computing device properly views the connection as a transmission medium. Transmission media can include a communication network and/or data links, carrier waves, wireless signals, and the like, which can be used to carry desired program or template code means or instructions in the form of computer-executable instructions or data structures and which can be accessed by a general purpose or special purpose computer.

Further, upon reaching various computer system components, program code in the form of computer-executable instructions or data structures can be transferred automatically or manually from transmission media to physical storage media (or vice versa). For example, computer-executable instructions or data structures received over a network or data link can be buffered in memory (e.g., RAM) within a network interface module (NIC), and then eventually transferred to computer system RAM and/or to less volatile physical storage media at a computer system. Thus, it should be understood that physical storage media can be included in computer system components that also (or even primarily) utilize transmission media.

One or more specific embodiments of the present disclosure are described herein. These described embodiments are examples of the presently disclosed techniques. Additionally, to provide a concise description of these embodiments, not all features of an actual embodiment may be described in the specification. It should be appreciated that in the development of any such actual implementation, as in any engineering or design project, numerous embodiment-specific decisions may be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure. All trademarks are the property of their respective owners.

The articles “a,” “an,” and “the” are intended to mean that there are one or more of the elements in the preceding descriptions. The terms “including,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A system for active load-pull measurements of a semiconductor device under test (DUT), comprising:
a controller;
a primary field-programmable gate array (FPGA) operably connected to the controller, the primary FPGA being configured to control and collect waveform data from a first plurality of vector signal analyzers (VSAs), each of the first plurality of VSAs comprising a respective analog-to-digital converter (ADC) connected to a respective ADC signal-conditioning circuit configured to directly capture radio frequency (RF) measurements of an input signal at an RF fundamental frequency of test and a plurality of harmonics, each ADC signal-conditioning circuit being configured to alter a signal amplitude and to isolate a wanted RF frequency of measurement at either the RF fundamental frequency of test or one of the plurality of harmonics to be received by its corresponding ADC,
first and second couplers respectively configured to generate the input signal for each ADC by extracting forward and reverse traveling waves at RF respectively from input and output ports of the DUT,
wherein the first plurality of VSAs are configured to capture the input signals directly at the RF fundamental frequency of test or the plurality harmonics over a user-specified frequency bandwidth centered at the RF fundamental frequency of test or one of the plurality harmonics and for a duration of time specified by a user,
wherein the FPGA is further configured to control and to send waveform data to a first plurality of vector signal generators (VSGs) respectively comprising digital-to-analog converters (DACs), each DAC being configured to transmit a respective signal directly at the RF fundamental frequency of test or at one of the plurality of harmonics, each DAC being respectively connected to a DAC signal-conditioning circuit configured to alter a signal amplitude of the signal transmitted from the DAC and filter out unwanted signals, the first plurality of VSGs being configured to transmit respective vector signals directly at the RF fundamental frequency of test or at one of the plurality of harmonics over a user-specified frequency bandwidth centered at the RF fundamental frequency of test or at one of the plurality of harmonics and for a duration of time determined by the user,
a first amplifier configured to receive a first RF vector signal from a first of the first plurality of VSGs and generate a first amplified RF signal, the first RF vector signal being generated from a forward traveling wave;
a second amplifier configured to receive a second RF vector signal from a second of the first plurality of VSGs and generate a second amplified RF signal, the second RF vector signal being generated from a reverse traveling wave;
a first circulator configured to:
receive the first amplified RF signal from the first amplifier; and
transmit the first amplified RF signal to the first coupler, the first coupler being further configured to transmit the first amplified RF signal to the DUT;
a second circulator configured to:
receive the second amplified RF signal from the second amplifier; and
transmit the second amplified RF signal to the second coupler, the second coupler being further configured to transmit the second amplified RF signal to the DUT;
a reference generator source configured to provide a waveform connected to a clock control, the clock control being configured to output a plurality of clock signals to the primary FPGA, the ADCs, and the DACs, the clock control signal being configured for synchronizing and triggering measurements for the first plurality of VSAs, the first and second vector signals transmitted to the first plurality of VSGs being synchronized by the clock signal,
wherein the controller is further configured to vector error-correct the captured waveform data and the transmitted RF waveforms to a user-specified calibrated reference plane for measurement of DUT parameters at the RF fundamental frequency of test and the plurality of harmonics and of system impedances at the input and output ports of the DUT at the RF fundamental frequency of test and the plurality of harmonics, the waveform measurement data being used to calculate an injection signal at a user-specified DUT port and frequency to alter the impedance at the DUT, the injection signal being synchronized with the input signal to measure a new system state,
wherein the measurement at the user-specified calibrated reference plane and frequency is checked against a user-specified impedance setting and user-specified accuracy tolerance, and
wherein, in response to the measurement not being within the user-specified accuracy tolerance, a new injection signal is calculated at the corresponding user-specified calibrated reference plane and user-specified frequency bandwidth, and the controller repeats testing until the user-specified accuracy the user-specified accuracy tolerance is reached or when a maximum number of attempts have been made.

2. The system of claim 1, further comprising:
a secondary FPGA operably connected to the controller, the secondary FPGA being connected to a second plurality of VSAs for measurement and impedance control of a second plurality of harmonics, the secondary FPGA being time-synchronized and time-aligned with the primary FPGA via a clock signal frequency and a trigger signal, the secondary FPGA being configured to control and to send waveform data to a second plurality of vector signal generators (VSGs) respectively comprising digital-to-analog converters (DACs), each DAC being configured to transmit a respective signal directly at the RF fundamental frequency of test or at one of the plurality of harmonics, each DAC being respectively connected to a DAC signal-conditioning circuit configured to alter a signal amplitude of the signal transmitted from the DAC and filter out unwanted signals, the second plurality of VSGs being configured to transmit respective vector signals directly at the RF fundamental frequency of test or at the one of the plurality of harmonics over the user-specified frequency bandwidth centered at the RF fundamental frequency of test or at the one of the plurality of harmonics and for the duration of time determined by the user,
wherein the plurality of injected signals at the RF fundamental frequency of test and the plurality of harmonics are combined at both the input and output ports of the DUT prior to being received by RF couplers to generate a vector error-corrected multi-harmonic signal to be received at input and output ports of the DUT.

3. The system of claim 1, further comprising:
one or more direct current (DC) power supplies; and
DC measurement circuitry operably connected to the one or more DC power supplies and to the primary FPGA,
wherein the DC measurement circuitry is configured to use the first plurality of VSAs with their respective ADCs to capture voltage and current at DC,
wherein ADC input waveforms are provided by the ADC signal-conditioning circuits that alter the amplitude of input waveform and remove unwanted frequencies within each input waveform,
wherein an input signal to each ADC signal-conditioning circuit is provided by voltage and current sense circuits, and is fed a signal from a sense resistor respectively placed at input or output ports of the DUT, and
wherein captured voltage and current waveforms are error-corrected to provide measurements at a common reference plane of RF measurements.

4. The system of claim 1, further comprising a plurality of DC bias tees respectively configured to supply DC power to input or output ports of a DUT.

5. The system of claim 1, further comprising:
a baseband test system configured to provide active load-pull of a DUT; and
baseband measurement circuitry comprising the first plurality of VSAs with respective ADCs to capture traveling waves collected at baseband frequencies and connected to the FPGA,
wherein an ADC input waveform is provided by each ADC signal-conditioning circuit that alter amplitude of the input waveform and remove unwanted frequencies within the input waveform, and
wherein the input signal to each signal conditioning circuits is provided by one of low-frequency couplers respectively at input and output ports of the DUT, the low-frequency couplers being configured to extract forward and reverse traveling waves measured at baseband frequencies.

6. The system of claim 1, wherein:
baseband active load-pull is applied to input and output ports of DUT; and
transmitted baseband signals from the first plurality of VSGs are sent to amplifiers connected to respective low-frequency DC bias tees that combine DC power provided by one or more direct current (DC) power supplies with a respective baseband signal provided by a respective VSG;
an amplified signal is then passed through a low-frequency coupler and then combined with an RF signal via the DC bias tees; and
signal amplitudes are vector error-corrected to present a desired signal at an RF-calibrated reference plane.

7. The system of claim 1, wherein:
the first plurality of VSAs with ADCs are connected to a main FPGA for baseband waveform capture; or
a second plurality of VSAs with ADCs are connected to a secondary FPGA for baseband waveform capture.

8. The system of claim 1, wherein:
the first plurality of VSGs with DACs are connected to a main FPGA for baseband waveform transmission; or
a second plurality of VSGs with DACs are connected to a secondary FPGA for baseband waveform transmission.

9. The system of claim 1, wherein a desired impedance and RF fundamental frequency of test are defined by a user before configuration information is provided.

10. The system of claim 1, wherein a desired impedance is set at an RF fundamental frequency of test and plurality of harmonics and baseband frequencies simultaneously by a user before configuration information is provided.

11. The system of claim 1, wherein:
at least one of the ADCs captures waveforms over a user-specified bandwidth centered at a user-specified RF fundamental frequency of test or plurality of harmonics;
a digitally-converted RF waveform is filtered to remove unwanted signals;
a filtered signal is frequency-converted and then digitally down-converted to a lower sample clock rate;
waveforms are then transferred to a controller for further processing;
at least one of the DACs transmits waveforms over bandwidth at a user specified RF fundamental frequency of test or harmonics;
where the controller transfers the waveform data to the primary FPGA and onwards to the at least one of the DACs at a sample rate based on a user-specified load-pull bandwidth requirement; and
the waveform data is digitally up-converted to a sample rate of DAC output, then frequency-converted to the RF fundamental frequency of test or one of the plurality of harmonics before conversion into an analog domain output signal.

12. The system of claim 1, wherein filtering, frequency down-conversion, and digital down-conversion of captured waveform data in a digital domain is performed within the primary FPGA or within one of the ADCs.

13. The system of claim 1 wherein filtering, digital up-conversion, and frequency up-conversion of transmitted waveform data in a digital domain is performed within the primary FPGA or within one of the DACs.

14. A method for a system for active load-pull measurements of a semiconductor device under test (DUT), the method comprising:
configuring and controlling a first plurality of vector signal analyzers (VSAs) to directly capture and to digitize measurements at input and output ports of the DUT at radio frequency (RF) fundamental frequency of test and at a plurality of harmonics,
wherein each VSA respectively comprises a high sample rate-based analog-to-digital converter (ADC) that directly captures waveforms at RF fundamental frequency of test and are connected to a respective ADC signal-conditioning circuit that control an amplitude of incoming signal and filter out unwanted frequency components;
the VSAs output a digitized signal to a primary field-programmable gate array (FPGA) and send waveform data to a controller;
the controller generates and transmits waveform data to the primary FPGA to output digitized data to a first plurality of vector signal generators (VSGs);
controlling the first plurality of VSGs to directly inject signals at input and output ports of the DUT at the RF fundamental frequency of test and the plurality of harmonics,
wherein the first plurality of VSGs respectively comprise high sample rate DACs that directly transmit signals at RF frequencies and are respectively connected to DAC signal-conditioning circuits that control an amplitude of an output signal and filter out unwanted frequency components;
the first plurality of VSGs transmit injected signal through RF couplers and direct current (DC) bias, both placed at respective input and output ports of the DUT;
the RF couplers pass through the transmitted injected signal while extracting forward and reverse traveling waves to feed into the first plurality of VSAs;
the controller configures a first of the first plurality of VSGs connected to the input port of the DUT and at RF fundamental frequency of test to inject a signal;
the controller assesses an impedance of the system at the RF fundamental frequency of test and the plurality of harmonics at both the input and the output ports of the DUT against a user-specified series of impedance targets at the RF fundamental frequency of tests and the plurality of harmonics at the input and the output ports of the DUT to a user-specified level of accuracy;
in response to not meeting one of the user-specified series of impedance targets, the controller calculates a magnitude and a phase of an injected signal required to present to the DUT with the one of the user-specified series of impedance targets, and configures one of the first plurality of VSGs at the input or the output port of the DUT at the RF fundamental frequency of test or one of the plurality of harmonics; and
the controller repeats a measurement to assess a newly-updated impedance being presented to the DUT, and in response to the repeated measurement not meeting a user-specified impedance target, calculates a new injected signal, and in response to the repeated measurement meeting the user-specified impedance target proceeds to completion of a measurement process.

15. The method of claim 14, wherein:
a digitized capture by one of the first plurality of VSAs at the RF fundamental frequency of test or one of the plurality of harmonics is filtered, frequency-converted, and digitally down-converted to a sample rate based on a user-specified load-pull bandwidth for onward transmission of a digitized waveform from the primary FPGA to the controller; and
the controller provides waveform data of one or more injected signals at one or more of the RF fundamental frequency of test or one of the plurality of harmonics at the input and output ports of the DUT at a sample rate based on user specified load-pull bandwidth to the primary FPGA for digital up-conversion to a sample rate of at least one of the DACs, and digital frequency-converted to the one or more of the RF fundamental frequency of test or one of the plurality of harmonics and filtering of unwanted signals to be transmitted out of the at least one of the DACs.

16. The method of claim 14, wherein digital functions of digital down-conversion, digital up-conversion, frequency mixing, and digital filtering are performed in a FPGA or in an associated ADC or DAC.

17. The method of claim 14, wherein:
a software stored in a non-transitory computer-readable medium includes instructions that, when executed, cause one or more processors to:
utilize a pre-determined system model that is vector error-corrected at the RF fundamental frequency of test and the plurality of harmonics;
generate a model of the DUT to describe a behavior of the DUT as a function of an injected input signal;
measure forward and reverse traveling waves at input and output ports of the DUT; and
calculate a correction injected signal to actively load-pull the DUT at a user-specified input or output port of the DUT and frequency that is based on a user target, a system model, or a DUT model; and
an injected signal for active load-pull is vector error-corrected to a calibrated reference plane.

18. The method of claim 14, further comprising:
determining a system model by injecting signals using the VSGs at the RF fundamental frequency of test and the plurality of harmonics at the input and output ports of the DUT connected as a through configuration;
the VSGs transmit signals through amplifiers, circulators, couplers, and DC bias tees; and
error vector-correcting measurements at the RF fundamental frequency of test and the plurality of harmonics using the determined system model.

19. The method of claim 14, wherein:
a predetermined system model that is vector error-corrected at the RF fundamental frequency of test and the plurality of harmonics and a DUT model as a function on an input signal are described over frequency using finite impulse response (FIR) filters; and
a resolution bandwidth of the input signal is determined as a function of captured signal bandwidth divided by a filter order.

20. The method of claim 14, wherein:
a resolution bandwidth of a received signal is described by a FIR filter used to describe a system model and DUT model; and
the resolution bandwidth of the received signal is determined to be less than, similar to, equal to, or greater than a resolution bandwidth of a user-selected input signal.

21. The method of claim 14, wherein a process of active load-pull applies at the RF fundamental frequency of test and the plurality of harmonics at the input and output ports of the DUT in parallel or in a sequential manner.

22. The method of claim 14, wherein the method is process applied at baseband frequencies at the input and output ports of the DUT.

23. The method of claim 14, wherein:
a respective passive tuner at each of an input or an output port of a DUT applies an impedance at the RF fundamental frequency of test and the plurality of harmonics; and
an impedance of each passive tuner can be set at a fixed setting or can be varied during an iterative process at the RF fundamental frequency of test or at least one of the plurality of harmonics.
